(19) United States
(12) Patent Application Publication
(10) Pub. No.: US 2025/0280716 A1
(43) Pub. Date: Sep. 4, 2025

(54) DISPLAY DEVICE

(71) Applicant: LG Display Co., Ltd., Seoul (KR)

(72) Inventors: Kwanghyun Choi, Seoul (KR); ChangSoo Kim, Paju-si (KR); SeongYeong Kim, Busan (KR)

(73) Assignee: LG Display Co., Ltd., Seoul (KR)

(21) Appl. No.: 19/056,586

(22) Filed: Feb. 18, 2025

(30) Foreign Application Priority Data
Feb. 29, 2024 (KR) 10-2024-0030309

(51) Int. Cl. H10K 59/80; H10K 59/121; H10K 59/131; H10K 59/35

(52) U.S. Cl. CPC H10K 59/879; H10K 59/1213; H10K 59/131; H10K 59/352

(57) ABSTRACT

A display device includes a first display area having a first emission area, a second emission area, and a transmittance area, and a second display area surrounding the first display area. Each of the sub pixels of the second display area including a first emitting diode, a second emitting diode, and a first lens corresponding to the first emitting diode, and a second lens corresponding to the second emitting diode. Each of the sub pixels of the first emission area including a third emitting diode, and a third lens corresponding to the third emitting diode. Each of the sub pixels of the second emission area including a fourth emitting diode and a fourth lens corresponding to the fourth emitting diode.

### CROSS-REFERENCE TO RELATED APPLICATIONS

This application claims the priority of Korean Patent Application No. 10-2024-0030309 filed on Feb. 29, 2024, in the Korean Intellectual Property Office, the disclosure of which is incorporated herein by reference.

### BACKGROUND

### Technical Field

The present disclosure relates to a display device, and particularly, improvement in the lifespan of a display device capable of controlling a viewing angle selectively.

### Discussion of the Related Art

The area of display devices displaying an electrical information signal visually has been progressed rapidly, and research into a variety of display devices has been conducted to enhance thinness, lightweight and performance such as low power consumption and the like of a display device.

Typical display devices may include a liquid crystal display (LCD) device, a field emission display (FED) device, an electro-wetting display (EWD) device, an organic light emitting display (OLED) device and the like.

Since as a self light-emitting display device, a field emission display device typical of an organic light emitting display device does not need a separate light source unlike a liquid crystal display device, the field emission display device may be manufactured as a lightweight and thin one. Additionally, the field emission display device is excellent in color embodiment, response speeds, viewing angles, contrast ratios (CR) as well as power consumption thanks to its low-voltage driving, and expected to be used in various fields.

In recent years, multi-media functions of a mobile terminal have improved. For example, a display device that has an optical electronic device such as a camera or a sensor basically built on the front surface thereof has been developed. However, the camera or the sensor disposed on the front surface of the display device may limit a screen design. To reduce a space occupied by the camera or the sensor on the front surface of the display device, a design comprising a notch or a punch hole may be applied, but the size of the screen is still limited, making it difficult to embody a full-screen display.

To embody a full-screen display, an area where low-resolution pixels are disposed may be provided in the screen of the display device, and a camera and/or various types of sensors may be disposed in the area where low-resolution pixels are disposed.

Further, with the advancement of modern technologies, a display device is used in various ways to provide information to the user. The display device comprises a variety of electronic devices requiring technologies for checking an input of the user and providing information in response to the checked input as well as an electronic display board simply delivering visual information in one direction.

As described above, the viewing angle of the display device is not limited, but needs to be limited selectively for the reasons of privacy protection and information protection and the like, when necessary.

### SUMMARY

Accordingly, embodiments of the present disclosure are directed to a display device that substantially obviates one or more of the problems due to limitations and disadvantages of the related art.

An aspect of the present disclosure is to provide a display device that may enhance resolution in a transmittance area where an optical electronic device such as a camera or a sensor and the like is disposed.

Another aspect of the present disclosure is to provide a display device that may limit a viewing angle selectively.

Yet another aspect of the present disclosure is to provide a display device that may secure an improved lifespan.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described, a display device comprises a substrate on which a plurality of sub pixels is disposed and that comprises a first display area comprising a first emission area, a second emission area and a transmittance area, and comprises a second display area surrounding the first display area. Each of the sub pixels disposed in the second display area comprises a first thin film transistor and a second thin film transistor; a first emitting diode comprising a first anode connecting to the first thin film transistor, a first emission layer and a cathode electrode; a second emitting diode comprising a second anode electrode connecting to the second thin film transistor, a second emission layer and the cathode electrode, and emitting light of the same color as light of the first emitting diode; and a lens layer comprising a first lens corresponding to the first emitting diode and refracting light from the first emitting diode and a second lens corresponding to the second emitting diode and refracting light from the second emitting diode. Each of the sub pixels disposed in the first emission area comprises a third thin film transistor; a third emitting diode comprising a third anode electrode connecting to the third thin film transistor, a third emission layer and a cathode electrode; and a third lens corresponding to the third emitting diode and refracting light from the third emitting diode, and each of the sub pixels disposed in the second emission area comprises a fourth thin film transistor; a fourth emitting diode comprising a fourth anode electrode connecting to the fourth thin film transistor, a fourth emission layer and a cathode electrode; and a fourth lens corresponding to the fourth emitting diode and refracting light from the fourth emitting diode.

Other detailed matters of the exemplary embodiments are included in the detailed description and the drawings.

According to the present disclosure, a camera or a sensor may be disposed at the lower end of an emitting diode or a touch electrode in the display area, preventing a display or a touch on the camera or the sensor from being cut/disconnected.

According to the present disclosure, the resolution of the transmittance area where an optical electronic device such as a camera or a sensor and the like is disposed may improve.

According to the present disclosure, the opening ratio of the display device may improve, and the density of current supplied to a sub pixel may decrease, securing improvement in the lifespan of an emitting diode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIGS. 1A-1D are schematic plan views of a display device of one embodiment;

FIG. 2 is a systematic block diagram of the display device of one embodiment;

FIG. 3 is a view of an example of disposition of a sub pixel of the display area of one embodiment;

FIG. 4 is a plan view of a pixel of a normal area of the display device of one embodiment;

FIG. 5 is a cross-sectional view along A-A′ and B-B′ of FIG. 4;

FIG. 6 is a plan view of a pixel of a first optical area of the display device of one embodiment;

FIG. 7 is a cross-sectional view along C-C′ of FIG. 6;

FIG. 8A is a circuit diagram of a sub pixel in the normal area of the display device of one embodiment;

FIG. 8B is a circuit diagram of a sub pixel of a first emission area in the first optical area of the display device of one embodiment;

FIG. 8C is a circuit diagram of a sub pixel of a second emission area in the first optical area of the display device of one embodiment;

FIG. 9 is a view for describing an example of driving of the normal area and the first optical area of the display device of one embodiment; and

FIG. 10 is a view of an example of the display device of one embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

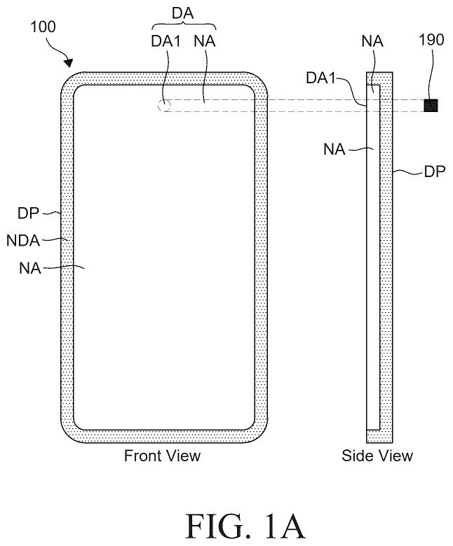

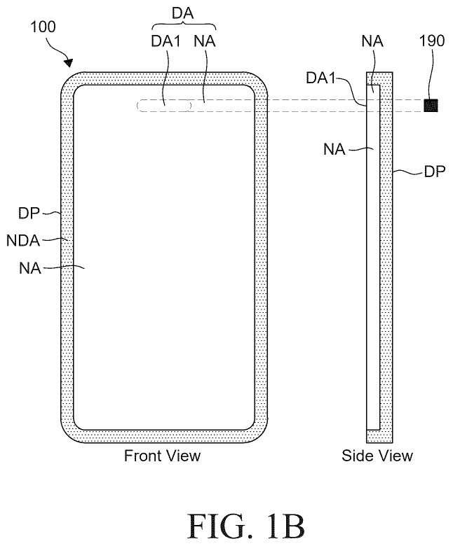

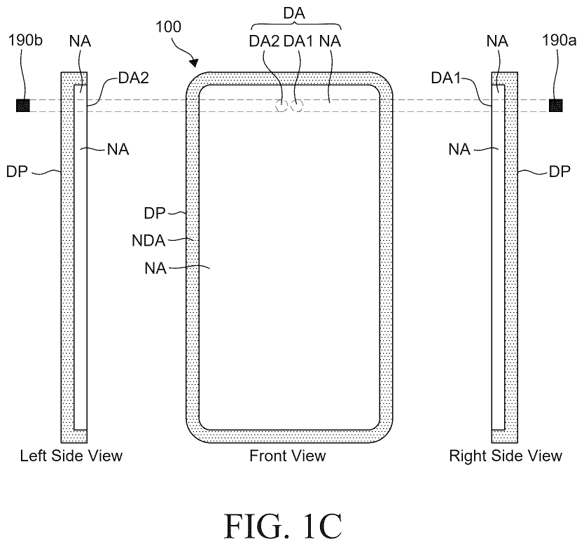

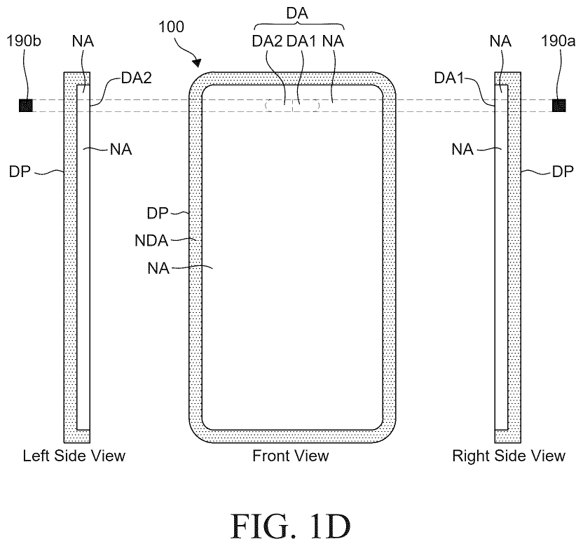

FIGS. 1A-1D are schematic plan views of a display device of one embodiment.

Referring to FIGS. 1A-1D, a display device 100 of one embodiment may comprise a display panel DP displaying an image and one or more optical electronic devices 190, 190a, 190b. The optical electronic devices 190, 190a, 190b may comprise a light receiving device such as a camera or a sensor that receives light.

The display panel DP is a panel for displaying an image to the user.

The display panel DP may be provided with a display element displaying an image, a driving element driving the display element, and lines and the like delivering various types of signals to the display element and the driving element. The display element may be defined in a different way depending on the sort of a display panel DP, and in the case where the display panel DP is an organic light emitting display panel, for example, the display element may be an organic light emitting diode comprising an anode, an emission layer and a cathode. Additionally, the display device 100 of one embodiment may be a flexible display device.

Further, the display panel DP may comprise a substrate, a plurality of insulation films on the substrate, a transistor layer, an emitting diode layer and the like. The display panel DP may comprise a plurality of sub pixels, and various type of signal lines for driving the plurality of sub pixels, to display an image. The signal lines may comprise a plurality of data lines, a plurality of gate lines, a plurality of power lines and the like. At this time, each of the plurality of sub pixels may comprise a transistor placed at the transistor layer and an emitting diode placed at the emitting diode layer.

The display panel DP may comprise a display area DA where an image is displayed and a non-display area NDA where an image is not displayed.

In the display area DA, a plurality of sub pixels constituting a plurality of pixels and a circuit for driving the plurality of sub pixels may be disposed. The plurality of sub pixels may be a minimum unit constituting the display area DA, and in each of the plurality of sub pixels, a display element may be disposed, and the plurality of sub pixels may constitute a pixel. For example, in each of the plurality of sub pixels, an organic light emitting diode comprising an anode, an emission layer and a cathode may be disposed, but not limited thereto. Additionally, in the circuit for driving the plurality of sub pixels, a driving element, lines and the like may be included. For example, the circuit may be comprised of a thin film transistor, a storage capacitor, a gate line, a data line and the like, but not limited thereto.

The non-display area NDA is bent and not seen from forward or covered by a case (not illustrated), and referred to as a bezel area.

In the non-display area NDA, various types of lines and circuits and the like for driving an organic light emitting diode of the display area DA may be disposed. For example, in the non-display area NDA, a link line for delivering signals to the plurality of sub pixels and circuits of the display area DA, a gate-in-panel (GIP) line, or a driving IC such as a gate driver IC and a data driver IC, and the like may be disposed but not limited thereto.

In FIGS. 1A-1D, the non-display area NDA surrounds the display area shaped into a rectangle, but the shapes and disposition of the display area DA and the non-display area NDA are not limited to the ones illustrated in FIGS. 1A-1D. That is, the display area DA and the non-display area NDA may have a shape appropriate for the design of an electronic device equipped with a display device 100. For example, the display area DA may be shaped into a pentagon, a hexagon, a circle, an oval and the like, for example.

The display device 100 may further comprise a variety of additional components for generating various types of signals or driving the pixels in the display area DA. The additional components for driving the pixels may comprise an inverter circuit, a multiplexer, an electrostatic discharge (ESD) circuit and the like. The display device 100 may also comprise an additional component in relation to a function in addition to the function of driving the pixels. For example, the display device 100 may further comprise additional components providing a touch sensing function, a user authentication function (e.g., a fingerprint recognition function), a multi-level pressure sensing function, a tactile feedback function and the like. The additional components described above may be placed in an external circuit connecting to the non-display area NDA and/or a connection interface.

Referring to FIGS. 1A-1D, one or more optical electronic devices 190, 190a, 190b are electronic components placed under the display panel DP (opposite to a viewing surface) in the display device 100 of the embodiments.

Light may go into the front surface (a viewing surface) of the display panel DP, pass though the display panel DP, and be delivered to one or more optical electronic devices 190, 190a, 190b placed under the display panel DP (opposite to a viewing surface).

One or more optical electronic devices 190, 190a, 190b may be a device that receives light having passed through the display panel DP, and based on received light, performs a predetermined function.

For example, the optical electronic device 190, 190a, 190b may comprise any one or more of a capturing device such as a camera (an image sensor) and the like, or a detection sensor such as a proximity sensor, an illuminance sensor and like.

Referring to FIGS. 1A-1D, the display area DA may comprise a normal area NA and one or more optical areas DA1, DA2 in the display device 100 of the embodiments.

One or more optical areas DA1, DA2 may be areas that overlap one or more optical electronic devices 190, 190a, 190b.

In the example of FIG. 1A, the display area DA may comprise a normal area NA and a first optical area DA1. Herein, at least part of the first optical area DA1 may overlap a first optical electronic device 190.

In FIG. 1A, the first optical area DA1 has a circular structure, but the shape of the first optical area DA1 of the embodiments is not limited thereto. For example, as illustrated in FIG. 1B, the first optical area DA1 may be shaped into an octagon, and may be shaped into a variety of polygons in addition to an octagon.

In the example of FIG. 1C, the display area DA may comprise a normal area NA, a first optical area DA1 and a second optical area DA2. In the example of FIG. 1C, the normal area NA may be between the first optical area DA1 and the second optical area DA2. Herein, at least part of the first optical area DA1 may overlap a first optical electronic device 190a, and at least part of the second optical area DA2 may overlap a second optical electronic device 190b.

In the example of FIG. 1D, the display area DA may comprise a normal area NA, a first optical area DA1 and a second optical area DA2. In the example of FIG. 1D, the normal area NA is not between the first optical area DA1 and the second optical area DA2. That is, the first optical area DA1 and the second optical area DA2 may contact each other. Herein, at least part of the first optical area DA1 may overlap the first optical electronic device 190a, and at least part of the second optical area DA2 may overlap the second optical electronic device 190b.

In one or more optical areas DA1, DA2, an image display structure and a light transmittance structure need to be formed. That is, since one or more optical areas DA1, DA2 are part of the display area DA, a sub pixel for displaying an image needs to be disposed in one or more optical areas DA1, DA2. In one or more optical areas DA1, DA2, a light transmittance structure for transmitting light to one or more optical electronic devices 190, 190a, 190b need to be formed.

One or more optical electronic devices 190, 190a, 190b are devices needed to receive light, but disposed behind (under, opposite to a viewing surface) the display panel DP, and receive light having passed through the display panel DP.

One or more optical electronic devices 190, 190a, 190b are not exposed to the front surface (a viewing surface) of the display panel DP. Accordingly, when the user sees the front surface of the display device 100, the optical electronic devices 190, 190a, 190b are not seen by the user.

For example, the first optical electronic device 190, 190a may be a camera, and the second optical electronic device 190b may be a detection sensor such as a proximity sensor, an illuminance sensor and the like. For example, the detection sensor may be an infrared sensor that senses infrared rays.

On the contrary, the first optical electronic device 190, 190a may be a detection sensor, and the second optical electronic device 190b may be a camera.

Hereinafter, the first optical electronic device 190, 190a is a camera, and the second optical electronic device 190b may be a detection sensor, for example, for convenience of description. Herein, the camera may be a camera lens or an image sensor.

In the case where the first optical electronic device 190, 190a is a camera, the camera may be disposed behind (under) the display panel DP, but may be a front camera that captures an image in the direction of the front surface of the display panel DP. Accordingly, the user may capture an image through a camera that is not seen from the viewing surface, while the user sees the viewing surface of the display panel DP.

The normal area NA and one or more optical areas DA1, DA2 included in the display area DA are areas that may display an image, but in the normal area NA, a light transmittance structure does not need to be formed, and in one or more optical areas DA1, DA2, a light transmittance structure needs to be formed.

Accordingly, one or more optical areas DA1, DA2 need to have a transmittance ratio at a predetermined level or above, and the normal area NA may not have light transmittance or have low light transmittance at a predetermined level or below.

For example, one or more optical areas DA1, DA2 and the normal area NA may have a different resolution, a different sub pixel disposition structure, a different number of sub pixels per unit surface area, a different electrode structure, a different line structure, a different electrode disposition structure, or a different line disposition structure, and the like.

For example, the number of sub pixels per unit surface area in one or more optical areas DA1, DA2 may be less than the number of sub pixels per unit surface area in the normal area NA. That is, the resolution of one or more optical areas DA1, DA2 may be less than the resolution of the normal area NA. At this time, the number of sub pixels per unit surface area may be a unit for measuring resolution, and may also be Pixels Per Inch (PPI) that denotes the number of pixels in one inch.

For example, the number of sub pixels per unit surface area in the first optical area DA1 may be less than the number of sub pixels per unit surface area in the normal area NA. Additionally, the number of sub pixels per unit surface area in the second optical area DA2 may be the number of sub pixels per unit surface area in the first optical area DA1 or greater.

The first optical area DA1 may have a variety of shapes such as a circle, an oval, a rectangle, a hexagon or an octagon and the like. The second optical area DA2 may have a variety of shapes such as a circle, an oval, a rectangle, a hexagon or an octagon and the like. The first optical area DA1 and the second optical area DA2 may have the same shape or a different shape.

Referring to FIG. 1D, in the case where the first optical area DA1 and the second optical area DA2 contact each other, an entire optical area comprising the first optical area DA1 and the second optical area DA2 may also have a variety of shape such as a circle, an oval, a rectangle, a hexagon or an octagon and the like.

Hereinafter, each of the first optical area DA1 and the second optical area DA2 has a circular shape, for example, for convenience of description.

In the case where the first optical electronic device 190, 190a that is not exposed to the outside and is hidden under the display panel DP is a camera in the display device 100 of one embodiment, the display device 100 of the embodiment may be a display to which a under display camera (UDC) technology is applied.

Accordingly, in the case of a display device 100 of the embodiment, since a notch or a camera hole for exposing a camera does not need to be formed at the display panel DP, the surface area of the display area DA does not decrease. As a result, since the display panel DP does not need to have a notch or a camera hole for exposing a camera, the size of the bezel area may decrease and limitations in design are removed, securing a high degree of freedom in design.

Although in the display device 100 of one embodiment, one or more optical electronic devices 190, 190a, 190b are hidden behind the display panel DP, one or more optical electronic devices 190, 190a, 190b need to receive light normally and perform a predetermined function normally.

Further, although in the display device 100 of one embodiment, one or more optical electronic devices 190, 190a, 190b are hidden behind the display panel DP and disposed to overlap the display area DA, an image needs to be displayed normally in one or more optical areas DA1, DA2 overlapping one or more optical electronic devices 190, 190a, 190b in the display area DA.

Thus, the display device 100 of one embodiment may have a structure in which the transmittance ratios of the first optical area DA1 and the second optical area DA2 overlapping the optical electronic devices 190, 190a, 190b improve.

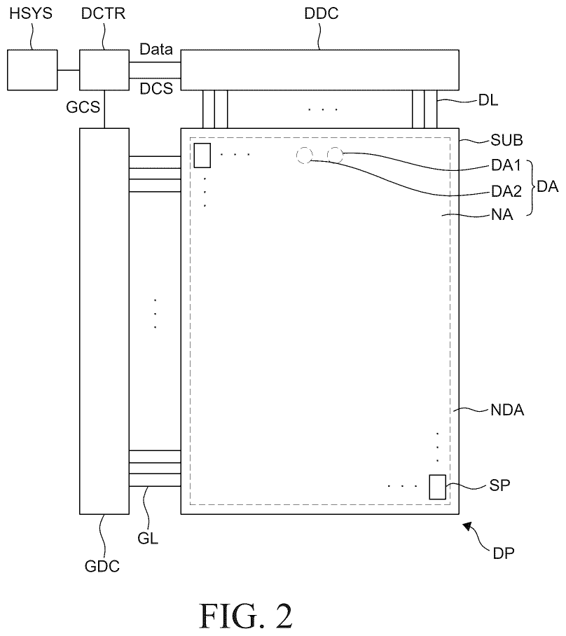

FIG. 2 is a systematic block diagram of the display device of one embodiment.

Referring to FIG. 2, the display device 100 may comprise a display panel DP and a display driving circuit as components for displaying an image. The display driving circuit as a circuit for driving the display panel DP may comprise a data driving circuit DDC, a gate driving circuit GDC and a display controller DCTR and the like.

The display panel DP may comprise a display area DA where an image is displayed and a non-display area NDA where an image is not displayed. The non-display area NDA may be an outer area of the display area DA and may also be a bezel area. All or part of the non-display area NDA may be an area that is seen from the front surface of the display device 100, or an area that is bent and not seen from the front surface of the display device 100.

The display panel DP may comprise a substrate SUB and a plurality of sub pixels SP disposed on the substrate SUB. Additionally, the display panel DP may further comprise various types of signal lines, to drive the plurality of sub pixels SP.

The display device 100 of the embodiments may be a self light-emitting OLED where a display panel DP emits light on its own, and each of the plurality of sub pixels SP may comprise an emitting diode.

For example, the display device 100 of the embodiments may be an organic light emitting display device where an emitting diode is embodied as an organic light emitting diode (OLED).

In another example, the display device 100 of the embodiments may be an inorganic light emitting display device where an emitting diode is embodied as an emitting diode based on an inorganic material. In yet another example, the display device 100 of the embodiments may be a quantum dot display device where an emitting diode is embodied as a quantum dot that is a semiconductor crystal emitting light on its own.

The structure of each of the plurality of sub pixels SP may vary depending on the type of a display device 100. For example, in the case where the display device 100 is a self light-emitting display device where a sub pixel SP emits light on its own, each sub pixel SP may comprise an emitting diode emitting light on its own, one or more transistors and one or more capacitors.

Various types of signal lines may comprise a plurality of data lines DL delivering data signals (also referred to as data voltages or image signals) and a plurality of gate lines GL delivering gate signals (also referred to as scan signals), and the like.

The plurality of data lines DL and the plurality of gate lines GL may cross each other. Each of the plurality of data lines DL may be disposed extending in a first direction. Each of the plurality of gate lines GL may be disposed extending in a second direction. The first direction may be a column direction, while the second direction may be a row direction. Alternatively, the first direction may be a row direction, while the second direction may be a column direction.

The data driving circuit DDC, as a circuit for driving the plurality of data lines DL, may output data signals to the plurality of data lines DL. The gate driving circuit GDC, as a circuit for driving the plurality of gate lines GL, may output gate signals to the plurality of gate lines GL.

The display controller DCTR, as a device for controlling the data driving circuit DDC and the gate driving circuit GDC, may control a driving timing for the plurality of data lines DL, and a driving timing for the plurality of gate lines GL.

The display controller DCTR may supply a data driving control signal DCS to the data driving circuit DDC to control the data driving circuit DDC and supply a gate driving control signal GCS to the gate driving circuit GDC to control the gate driving circuit GDC.

The display controller DCTR may receive input image data from a host system HSYS, and based on the input image data, supply image data Data to the data driving circuit DDC.

The data driving circuit DDC may supply data signals to the plurality of data lines DL under driving timing control of the display controller DCTR. The data driving circuit DDC may receive digital-type image data from the display controller DCTR, convert the image data received to analogue-type data signals, and output the data signals to the plurality of data lines DL.

The gate driving circuit GDC may supply gate signals to the plurality of gate lines GL under the timing control of the display controller DCTR. The gate driving circuit GDC may be supplied with a first gate voltage that corresponds to a turn-on level voltage and a second gate voltage that corresponds to a turn-off level voltage, together with various types of gate driving control signals GCS, generate gate signals, and supply the gate signals generated to the plurality of gate lines GL.

The gate driving circuit GDC supplies a gate signal to the gate line GL according to a gate driving control signal GCS supplied from the display controller DCTR. The gate driving circuit GDC may be disposed at one side or both sides of the display panel DP, based on the Gate In Panel (GIP) method.

The gate driving circuit GDC outputs a gate signal to the plurality of gate lines GL consecutively under the control of the display controller DCTR. The gate driving circuit GDC may shift gate signals by using a shift register and supply the signals to the gate lines GL consecutively.

The gate signal may comprise a scan signal SC and an emission control signal EM in the display device. The scan signal SC comprises a scan signal pulse that swings between a first gate voltage and a second gate voltage. The emission control signal EM may comprise an emission control signal pulse that swings between a third gate voltage and a fourth gate voltage.

The scan pulse synchronizes with a data voltage Vdata and selects sub pixels SP of a line to which data is to be written. The emission control signal EM defines emission time of each sub pixel SP.

The gate driving circuit GDC may comprise an emission control signal driver EDC outputting an emission control signal EM and at least one or more scan drivers SDC outputting a scan signal SC.

The emission control signal driver EDC outputs an emission control signal EM in response to a start pulse and a shift clock from the display controller DCTR, and based on the shift clock, shifts an emission control signal pulse consecutively.

At least one or more scan drivers SDC outputs a scan signal SC in response to a start pulse and a shift clock from the display controller DCTR, and in accordance with a shift clock timing, shifts a scan signal pulse.

In the gate driving circuit GDC disposed based on the GIP method, the shift register may be configured to be symmetrical at both sides of the display area DA. Additionally, in the gate driving circuit GDC, the shift register at one side of the display area DA may comprise at least one scan driver SDC and the emission control signal driver, and the shift register at the other side of the display area DA may comprise at least one scan driver SDC, but not limited thereto. The emission control signal driver EDC and at least one scan driver SDC may be disposed in a different way depending on embodiments.

The data driving circuit DDC may be connected to the display panel DP based on tape automated bonding (TAB), or connected to a boding pad of the display panel DP based on the chip on glass (COG) method or chip on panel (COP) method, or embodied based on the chip on film (COF) method, and connected to the display panel DP.

The gate driving circuit GDC may be connected to the display panel DP based on the tape automated bonding (TAB) method, or connected to a boding pad of the display panel DP based on the chip on glass (COG) method or chip on panel (COP) method, or connected to the display panel DP based on the chip on film (COF) method. Alternatively, the gate driving circuit GDC may be formed in the non-display area NDA of the display panel DP as a gate in panel (GIP) type-one. The gate driving circuit GDC may be disposed on the substrate or connected to the substrate. That is, the gate driving circuit GDC may be disposed in the non-display area NDA of the substrate in the case where the gate driving circuit GDC is a GIP-type one. The gate driving circuit GDC may be connected to the substrate in the case where the gate driving circuit GDC is a chip on glass (COG)-type one, a chip on film (COF)-type one and the like.

Additionally, at least one of the data driving circuit DDC and the gate driving circuit GDC may be disposed in the display area DA of the display panel DP. For example, at least one of the data driving circuit DDC and the gate driving circuit GDC may be disposed not to overlap the sub pixels SP, or to overlap the sub pixels SP partially or entirely.

The data driving circuit DDC may be connected to one side (e.g., the upper side or the lower side) of the display panel DP. Depending on a driving method, a panel design method and the like, the data driving circuit DDC may be connected to both sides (e.g., the upper side and the lower side) of the display panel DP, or connected to two or more of four lateral surfaces of the display panel DP.

The gate driving circuit GDC may also be connected to one side (e.g., the left side or the right side) of the display panel DP. Depending on a driving method, a panel design method and the like, the gate driving circuit GDC may be connected to both sides (e.g., the left side and the right side) of the display panel DP, or connected to two or more of four lateral surfaces of the display panel DP.

The display controller DCTR may be embodied as a part apart from the data driving circuit DDC, or integrated with the data driving circuit DDC and embodied as an integrated circuit.

The display controller DCTR may be a timing controller that is used in ordinary display technologies, or a control device that comprises a timing controller and further performs another control function, or a control device different from a timing controller, or a circuit in a control device. The display controller DCTR may be embodied as an integrated circuit IC, a field programmable gate1 array (FPGA), an application specific integrated circuit (ASIC), or a variety of circuits such as a processor and the like or an electronic part.

The display controller DCTR may be mounted on a printed circuit board and a flexible printed circuit and the like, and electrically connected to the data driving circuit DDC and the gate driving circuit GDC through the printed circuit board, and the flexible printed circuit and the like.

The display controller DCTR may tranceive a signal with the data driving circuit DDC according to one or more predetermined interfaces. The interface may comprise a low voltage differential signaling (LVDS) interface, an embedded clock point-to-point interface (EPI), a serial peripheral interface (SPI), and the like, for example.

The display device 100 of the embodiments may comprise a touch sensor, and a touch sensing circuit that senses the touch sensor and detects whether a touch occurs with a touch object such as a finger or a pen and the like or detects a touch position, to provide a touch sensing function further as well as an image displaying function.

The touch sensing circuit may further comprise a touch driving circuit that drives and senses the touch sensor, and generates and outputs touch sensing data, a touch controller that senses occurrence of a touch or detects a touch position by using the touch sensing data, and the like.

The touch sensor may comprise a plurality of touch electrodes. The touch sensor may further comprise a plurality of touch lines for connecting the plurality of touch electrode and the touch driving circuit electrically.

The touch sensor may be outside the display panel DP, in the form of a touch panel, or may be disposed in the display panel DP. In the case where the touch sensor is outside the display panel DP in the form of a touch panel, the touch sensor is referred to as an external one. In the case where the touch sensor is an external one, the touch panel and the display panel DP may be manufactured in a separate manner and coupled during assembly. An external touch panel may comprise a substrate for a touch panel, and a plurality of touch electrodes on the substrate for a touch panel, and the like.

In the case where the touch sensor is in the display panel DP, the touch sensor may be formed on the substrate SUB, together with signal lines and electrodes and the like in relation to driving of a display, during manufacturing of the display panel DP.

The touch driving circuit TDC may supply a touch driving signal to at least one of the plurality of touch electrodes, and generate touch sensing data by sensing at least one of the plurality of touch electrodes.

The touch sensing circuit may perform touch sensing based on the self-capacitance sensing method or the mutual-capacitance sensing method.

In the case where the touch sensing circuit performs touch sensing based on self-capacitance sensing, the touch sensing circuit may perform touch sensing based on capacitance between each touch electrode and a touch object (e.g., a finger, a pen and the like).

In self-capacitance sensing, each of the plurality of touch electrodes may serve as a driving touch electrode and a sensing touch electrode. The touch driving circuit TDC may drive all or part of the plurality of touch electrodes and sense all or part of the plurality of touch electrodes.

In the case where the touch sensing circuit performs touch sensing based on mutual-capacitance sensing, the touch sensing circuit may perform touch sensing based on capacitance between the touch electrodes.

In mutual-capacitance sensing, the plurality of touch electrodes is divided into driving touch electrodes and sensing touch electrodes. The touch driving circuit may drive the driving touch electrode and sense the sensing touch electrodes.

A touch driving circuit and a touch controller included in the touch sensing circuit may be embodied as a separate device, or embodied as one device. Additionally, the touch driving circuit and the data driving circuit DDC may be embodied as a separate device, or embodied as one device.

Further, the display device 100 may further comprise a power supply circuit and the like supplying various types of power sources to the display driving circuit and/or the touch sensing circuit.

The display device 100 of the embodiments may be a mobile terminal such as a smartphone, a tablet and the like, or a monitor or a television TV and the like of different sizes, but not limited thereto, and may be different types and different sizes of displays outputting information or an image.

As described above, the display area DA in the display panel DP may comprise a normal area NA and one or more optical areas DA1, DA2.

The normal area NA and one or more optical areas DA1, DA2 are areas capable of displaying an image. However, the normal area NA is an area where a light transmitting structure does not need to be formed, and one or more optical areas DA1, DA2 are areas where a light transmitting structure needs to be formed.

As described above, the display area DA in the display panel DP may comprise a normal area NA and one or more optical areas DA1, DA2.

Hereinafter, suppose that the display area DA comprises both the first optical area DA1 and the second optical area DA2 for convenience of description (FIGS. 1C and 1D).

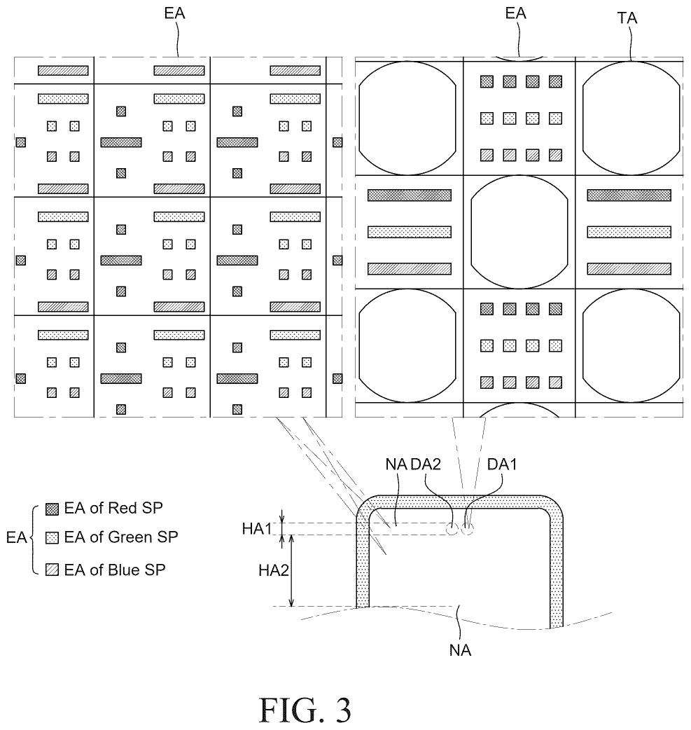

FIG. 3 is a view of an example of disposition of a sub pixel of the display area of one embodiment.

FIG. 3 shows the disposition of a sub pixel SP in three areas NA, DA1, DA2 included in the display area DA of the display panel of the embodiment.

Referring to FIG. 3, a plurality of sub pixels SP may be disposed in each of the normal area NA, the first optical area DA1 and the second optical area DA2 included in the display area.

In an example, the plurality of sub pixels SP may comprise a red sub pixel Red SP emitting red light, a green sub pixel Green SP emitting green light, and a blue sub pixel Blue SP emitting blue light.

Accordingly, each of the normal area NA, the first optical area DA1 and the second optical area DA2 may comprise an emission area EA of the red sub pixel Red SP, an emission area EA of the green sub pixel Green SP, an emission area EA of the blue sub pixel Blue SP.

Referring to FIG. 3, the normal area NA may comprise an emission area EA without comprising a light transmitting structure.

However, the first optical area DA1 and the second optical area DA2 need to comprise a light transmitting structure as well as an emission area EA.

Accordingly, the first optical area DA1 may comprise an emission area EA and a transmittance area TA.

The emission area EA and the transmittance area TA may be distinguished depending on whether light is transmitted or not. That is, the emission area EA may be an area where light transmittance is impossible, while the transmittance area TA may be an area where light transmittance is possible.

Additionally, the emission area EA and the transmittance area TA may be distinguished depending on whether a specific metal layer is formed or not. For example, a cathode electrode may be formed in the emission area EA, and may not be formed in the transmittance area TA. Additionally, a light shielding layer may be formed in the emission area EA, and may not be formed in the transmittance area TA.

In the transmittance area TA, a deposition prevention layer (not illustrated) made of an organic material may be disposed on the same planar surface as the cathode electrode. During formation of the cathode electrode, a cathode electrode material may not be deposited on the deposition prevention layer, and the cathode electrode may be selectively formed on the substrate SUB.

Since the first optical area DA1 comprises a transmittance area TA, the first optical area DA1 may transmit light.

Though not illustrated in FIG. 3, the second optical area DA2 may also comprise an emission area EA and a transmittance area TA. Since the second optical area DA2 also comprises the transmittance area TA, both the first optical area DA1 and the second optical area DA2 may transmit light. The structures and arrangements of the emission area EA and the transmittance area TA of the first optical area DA1 may be the same as or different from the structures and arrangements of the emission area EA and the transmittance area TA of the second optical area DA2.

Specifically, the transmittance ratio (a transmittance degree) of the first optical area DA1 and the transmittance ratio (a transmittance degree) of the second optical area DA2 may be the same. At this time, the shape or size of the transmittance area TA of the first optical area DA1 may be the same as the shape or size of the transmittance area TA of the second optical area DA2. Alternatively, although the shape or size of the transmittance area TA of the first optical area DA1 is different from the shape or size of the transmittance area TA of the second optical area DA2, a ratio of the transmittance area TA in the first optical area DA1 may be the same as a ratio of the transmittance area TA in the second optical area DA2.

On the contrary, the transmittance ratio (a transmittance degree) of the first optical area DA1 may be different from the transmittance ratio (a transmittance degree) of the second optical area DA2.

At this time, the shape or size of the transmittance area TA of the first optical area DA1 may be different from the shape or size of the transmittance area TA of the second optical area DA2. Alternatively, although the shape or size of the transmittance area TA of the first optical area DA1 is the same as the shape or size of the transmittance area TA of the second optical area DA2, a ratio of the transmittance area TA in the first optical area DA1 may be different from a ratio of the transmittance area TA in the second optical area DA2.

For example, in the case where the first optical electronic device with which the first optical area DA1 overlaps is a camera while the second optical electronic device with which the second optical area DA2 overlaps is a detection sensor, the camera may need a greater amount of light than the detection sensor.

Accordingly, the transmittance ratio (a transmittance degree) of the first optical area DA1 may be greater than the transmittance ratio (a transmittance degree) of the second optical area DA2. At this time, the transmittance area TA of the first optical area DA1 may have a greater size than the transmittance area TA of the second optical area DA2. Alternatively, although the size of the transmittance area TA of the first optical area DA1 is the same as the size of transmittance area TA of the second optical area DA2, a ratio of the transmittance area TA in first optical area DA1 may be greater than a ratio of the transmittance area TA in the second optical area DA2.

Hereinafter, for convenience description, suppose that the transmittance ratio (a transmittance degree) of the first optical area DA1 is the same as the transmittance ratio (a transmittance degree) of the second optical area DA2, for example.

In the embodiment, the transmittance area TA illustrated in FIG. 3 may also be referred to as a transparent area, and a transmittance ratio may also be referred to as transparency.

In one embodiment, suppose that the first optical area DA1 and the second optical area DA2 are placed at the upper end of the display area of the display panel and disposed side by side in a left-right direction, as illustrated in FIG. 3.

Referring to FIG. 3, a display area, where the first optical area DA1 and the second optical area DA2 are disposed, in a horizontal direction is referred to as a first horizontal display area HA1, and a display area, where the first optical area DA1 and the second optical area DA2 are not disposed, in the horizontal direction is referred to as a second horizontal display area HA2.

The first horizontal display area HA1 may comprise a normal area NA, a first optical area DA1 and a second optical area DA2. On the contrary, the second horizontal display area HA2 may comprise a normal area NA only.

Referring to FIG. 3, the first optical area DA1 included in the first horizontal display area HA1 may comprise an emission area EA and a transmittance area TA. In the first optical area DA1, the outer area of the transmittance area TA may comprise the emission area EA.

Referring to FIG. 3, the emission area EA may be disposed between the transmittance areas TA that are adjacent to each other in the left-right direction, at the first optical area DA1 in the first horizontal display area HA1. The emission area EA may be disposed between two transmittance areas TA that are adjacent to each other in an up-down direction, at the first optical area DA1 in the first horizontal display area HA1.

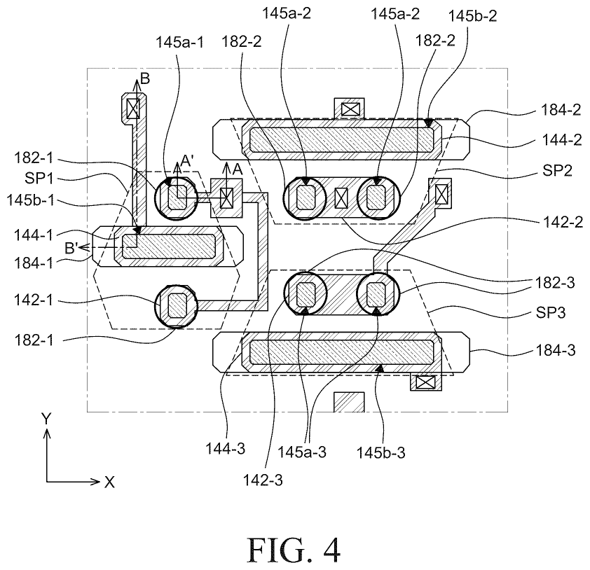

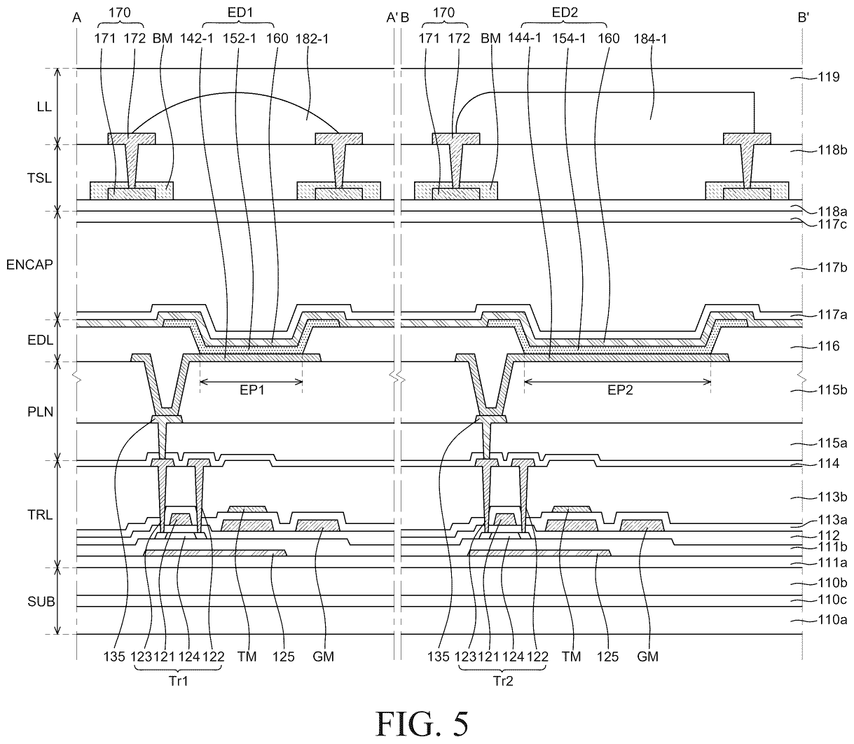

Hereinafter, the structure of the normal area NA of the display device 100 of one embodiment is specifically described with reference to FIGS. 4 and 5.

FIG. 4 is a plan view of a pixel of a normal area NA of the display device of one embodiment.

In FIG. 4, a plurality of first anode electrodes 142-1, 142-2, 142-3, second anode electrodes 144-1, 144-2, 144-3, first openings 145a-1, 145a-2, 145a-3, second openings 145b-1, 145b-2, 145b-3, first lenses 182-1, 182-2, 182-3 and second lenses 184-1, 184-2, 184-3 in each of first to third sub pixels SP1, SP2, SP3 of a pixel of a light emitting display device are only illustrated.

As illustrated in FIG. 4, a pixel of the light emitting display device of one embodiment comprises first to third sub pixels SP1, SP2, SP3, and the first sub pixel SP1 may be a red sub pixel, the second sub pixel SP2 may be a green sub pixel, and the third sub pixel SP3 may be a blue sub pixel.

Herein, the second sub pixel SP2 and the third sub pixel SP3 may be disposed along a Y direction, and the first sub pixel SP1 may be disposed along an X direction with respect to the second sub pixel SP2 and the third sub pixel SP3.

Each of the first to third sub pixels SP1, SP2, SP3 described above may have a polygonal shape. At this time, the first to third sub pixels SP1, SP2, SP3 may have a different shape. The shapes of the first to third sub pixels SP1, SP2, SP3 may not be limited and may vary.

The first to third sub pixels SP1, SP2, SP3 may have a different surface area. The surface areas of the first to third sub pixels SP1, SP2, SP3 may be determined considering the lifespan and emission efficiency of an emitting diode provided in each sub pixel. At this time, the lifespan of a red emitting diode is the longest. To uniformize a lifespan, the surface area of the first sub pixel SP1 is less than the surface area of each of the second sub pixel SP2 and the third sub pixel SP3, but not limited thereto. A ratio of the surface areas of the first to third sub pixels SP1, SP2, SP3 may vary.

The first to third sub pixels SP1, SP2, SP3 respectively comprise a first emitting diode ED1 and a second emitting diode ED2. The first emitting diode ED1 and the second emitting diode ED2 may have the same structure and embody the same color.

As illustrated in FIGS. 4-5, the first sub pixel SP1 comprises a first anode electrode 142-1 provided in a first emission part EP1, and a second anode electrode 144-1 provided in a second emission part EP2. The first anode electrode 142-1 provided in the first sub pixel SP1 connects to a first thin film transistor Tr1 through a first drain contact hole. Additionally, the second anode electrode 144-1 provided in the first sub pixel SP1 connects to a second thin film transistor Tr2 through a second drain contact hole.

Additionally, the second sub pixel SP2 also comprises a first anode electrode 142-2 provided in a first emission part EP1, and a second anode electrode 144-2 provided in a second emission part EP2. The first anode electrode 142-2 provided in the second sub pixel SP2 connects to a first thin film transistor Tr1 through a first drain contact hole. Additionally, the second anode electrode 144-2 provided in the second sub pixel SP2 connects to a second thin film transistor Tr2 through a second drain contact hole.

Additionally, the third sub pixel SP3 also comprises a first anode electrode 142-3 provided in a first emission part EP1, and a second anode electrode 144-3 provided in a second emission part EP2. The first anode electrode 142-3 provided in the third sub pixel SP3 connects to a first thin film transistor Tr1 through a first drain contact hole. Additionally, the second anode electrode 144-3 provided in the third sub pixel SP3 connects to a second thin film transistor Tr2 through a second drain contact hole.

In each of the first to third sub pixels SP1, SP2, SP3, at least one first opening 145a-1, 145a-2, 145a-3 is provided on the first anode electrode 142-1, 142-2, 142-3. In each of the first to third sub pixels SP1, SP2, SP3, at least one second opening 145b-1, 145b-2, 145b-3 is provided on the second anode electrode 144-1, 144-2, 144-3. On an X-Y plan view, each of the first openings 145a-1, 145a-2, 145a-3 may have a shape in which the length of each of the first openings 145a-1, 145a-2, 145a-3 in the X direction is substantially the same as the length thereof in the Y direction, and the second openings 145b-1, 145b-2, 145b-3 may have a polygonal shape in which the length of each of the second openings 145b-1, 145b-2, 145b-3 in the X direction is greater than the length thereof in the Y direction. Further, the surface area of each of the second openings 145b-1, 145b-2, 145b-3 may be greater than the surface area of at least one first opening 145a-1, 145a-2, 145a-3.

Specifically, in the first sub pixel SP1, two first openings 145a-1 may be disposed on the first anode electrode 142-1, and one second opening 145b-1 may be disposed on the second anode electrode 144-1. The two first openings 145a-1 and the one second opening 145b-1 described above may be spaced in the Y direction.

In the second sub pixel SP2, two first openings 145a-2 may be disposed on the first anode electrode 142-2 in the X direction, and one second opening 145b-2 may be disposed on the second anode electrode 144-2. The two first openings 145a-2 and the one second opening 145b-2 described above may be spaced in the Y direction.

In the third sub pixel SP3, two first openings 145a-3 may be disposed on the first anode electrode 142-3 in the X direction, and one second opening 145b-3 may be disposed on the second anode electrode 144-3. The two first openings 145a-3 and the one second opening 145b-3 described above may be spaced in the Y direction.

In response to each of the first openings 145a-1, 145a-2, 145a-3, a half-spherical first lens 182-1, 182-2, 182-3 is disposed, and in response to the second openings 145b-1, 145b-2, 145b-3, a half-cylindrical second lens 184-1, 184-2, 184-3 is disposed.

Each of the first lenses 182-1, 182-2, 182-3 is disposed to cover each of the first openings 145a-1, 145a-2, 145a-3. On an X-Y planar surface, the surface area of each of the first lenses 182-1, 182-2, 182-3 may be greater than the surface area of each of the first openings 145a-1, 145a-2, 145a-3. Additionally, each of the second lenses 184-1, 184-2, 184-3 is disposed to cover each of the second openings 145b-1, 145b-2, 145b-3. On an X-Y planar surface, the surface area of each of the second lenses 184-1, 184-2, 184-3 may be greater than the surface area of each of the second openings 145b-1, 145b-2, 145b-3.

Specifically, in the first sub pixel SP1, two first lenses 182-1 may be disposed to cover two first opening 145a-1, and one second lens 184-1 may be disposed to cover one second opening 145b-1. In the second sub pixel SP2, two first lenses 182-2 may be disposed to cover each of two first openings 145a-2, and one second lens 184-2 may be disposed to cover one second opening 145b-2. Additionally, in the third sub pixel SP3, two first lenses 182-3 may be disposed to cover each of two first openings 145a-3, and one second lens 184-3 may be disposed to cover one second opening 145b-3.

Accordingly, the plurality of first lenses 182-1, 182-2, 182-3 corresponds to the first emission part EP1 of each sub pixel SP1, SP2, SP3. Additionally, the plurality of second lenses 184-1, 184-2, 184-3 corresponds to the second emission part EP2 of each sub pixel SP1, SP2, SP3.

As described above, in the light emitting display device of one embodiment, a half-spherical first lens 182-1, 182-2, 182-3 is provided in response to the first anode electrode 142-1, 142-2, 142-3, and a half-cylindrical second lens 184-1, 184-2, 184-3 is provided in response to the second anode electrode 144-1, 144-2, 144-3, to limit a viewing angle. At this time, a direction in which the viewing angle of the first lens 182-1, 182-2, 182-3 is limited is different from a direction in which the viewing angle of the second lens 184-1, 184-2, 184-3 is limited, and based on selective driving, a wide viewing angle and a narrow viewing angle may be embodied.

Hereinafter, a first emitting diode ED1 and a second emitting diode ED2 of the normal area NA are described with reference to FIG. 5.

FIG. 5 is a cross-sectional view along A-A′ and B-B′ of FIG. 4. FIG. 5 is a cross-sectional view of a first emitting diode ED1 and a second emitting diode ED2 of the first sub pixel SP1 of the normal area NA.

In FIG. 5, a cross-sectional view of the first sub pixel SP1 is only illustrated, but the second sub pixel SP2 and the third sub pixel SP3 may have the same structure as the first sub pixel SP1 except that in the case of a second sub pixel SP2 and a third sub pixel SP3, the first emission part EP1, the second emission part EP2, the first anode electrode 142-2, 142-3, the second anode electrode 144-2, 144-3, the first lens 182-2, 182-3, and the second lens 184-2, 184-3 have a different size, and that the first anode electrode 142-2, 142-3 and the second anode electrode 144-2, 144-3 connect to a pixel circuit disposed in a corresponding sub pixel.

Referring to FIG. 5, in the normal area NA, a transistor layer TRL may be disposed on a substrate SUB, and a planarization layer PLN may be disposed on the transistor layer TRL. An emitting diode layer EDL may be disposed on the planarization layer PLN, an encapsulation layer ENCAP may be disposed on the emitting diode layer EDL, a touch sensing layer TSL may be disposed on the encapsulation layer ENCAP, and a lens layer LL may be disposed on the touch sensing layer TSL.

The substrate SUB as an element for supporting a variety of components included in the display device 100 may be made of an insulation material. The substrate SUB may comprise a first substrate 110a, a second substrate 110b and an interlayer insulation film 110c. For example, the first substrate 110a and the second substrate 110b may be a polyimide (PI) substrate. The interlayer insulation film 110c may be disposed between the first substrate 110a and the second substrate 110b. The substrate SUB, as described above, is comprised of the first substrate 110a, the second substrate 110b and the interlayer insulation film 110c, to prevent moisture from infiltrating.

The first to third sub pixels SP1, SP2, SP3 are defined on the substrate SUB. For example, the first sub pixel SP1, the second sub pixel SP2 and the third sub pixel SP3 are defined on the substrate SUB. Each of the first sub pixel SP1, the second sub pixel SP2 and the third sub pixel SP3 has a first emission part EP1 and a second emission part EP2.

In the normal area NA, various types of patterns 131, 132, 133, 134, insulation films 111a, 111b, 112, 113a, 113b, 114 and metal patterns TM, GM, 135 for forming a transistor such as a driving transistor and the like may be disposed on the transistor layer TRL.

A driving transistor may comprise a first thin film transistor Tr1 corresponding to the first emission part EP1, and a second thin film transistor Tr2 corresponding to the second emission part EP2. The first thin film transistor Tr1 and the second thin film transistor Tr2 may respectively comprise a gate electrode 121, a source electrode 122, a drain electrode 123 and an active layer 124.

Hereinafter, a stack structure of the transistor layer TRL is described specifically.

A multi-buffer layer 111a is disposed on the second substrate 110b, and a metal layer 125 may be disposed on the multi-buffer layer 111a. The metal layer 125 may serve as a light shield and be referred to as a light shielding layer.

An active buffer layer 111b may be disposed on the multi-buffer layer 111a and the metal layer 125, and the active layer 124 of the first thin film transistor Tr1 and the second thin film transistor Tr2 may be disposed on the active buffer layer 111b. For example, the active layer 124 may be formed of poly silicon (p-Si), amorphous silicon (a-Si) or oxide semiconductor, but not limited thereto.

A gate insulation film 112 may be disposed on the active layer 124. The gate insulation film 112 may be made of silicon oxide (SiOx), silicon nitride (SiNx) or multiple layers thereof.

Additionally, a gate electrode 121 may be disposed on the gate insulation film 112. The gate electrode 121 is disposed to overlap the active layer 124, on the gate insulation film 112. The gate electrode 121 may be formed of a variety of electrically conductive materials, e.g., magnesium (Mg), aluminum (Al), nickel (Ni), chromium (Cr), molybdenum (Mo), tungsten (W), gold (Au) or an alloy thereof, and the like, but not limited thereto.

A gate material layer GM may be disposed on the gate insulation film 112, at a position different from the position where the first thin film transistor Tr1 and the second thin film transistor Tr2 are formed.

A first interlayer insulation film 113a may be disposed on the gate electrode 121 and the gate material layer GM. A metal pattern TM may be disposed on the first interlayer insulation film 113a. A second interlayer insulation film 113b may be disposed, covering the metal pattern TM disposed on the first interlayer insulation film 113a.

A source electrode 122 and a drain electrode 123 may be disposed on the second interlayer insulation film 113b.

The source electrode 122 and the drain electrode 123 may connect respectively to one side and the other side of a semiconductor layer 134 through a contact hole provided at the second interlayer insulation film 113b, the first interlayer insulation film 113a and the gate insulation film 112. The source electrode 122 and the drain electrode 123 may be formed of a variety of electrically conductive materials, e.g., magnesium (Mg), aluminum (Al), nickel (Ni), chromium (Cr), molybdenum (Mo), tungsten (W), gold (Au) or an alloy thereof, but not limited thereto.

At the active layer 124, a portion overlapping the gate electrode 121 is a channel area. One of the source electrode 122 and the drain electrode 123 connects to one side of the channel area at the active layer 124, and the rest connects to the other side of the channel area at the active layer 124.

A passivation layer 114 may be disposed on the source electrode 122 and the drain electrode 123. The passivation layer 114 is to protect the first thin film transistor Tr1 and the second thin film transistor Tr2, and is made of an inorganic film such as silicon oxide (SiOx), silicon nitride (SiNx) or multiple layers thereof.

A planarization layer PLN may be disposed on the transistor layer TRL. The planarization layer PLN may comprise a first planarization layer 115a and a second planarization layer 115b. The planarization layer PLN protects the first thin film transistor Tr1 and the second thin film transistor Tr2 and planarizes the upper portions thereof. The first planarization layer 115a may be disposed on the passivation layer 114, and a connection electrode 135 may be disposed on the first planarization layer 115a.

The connection electrode 135 may connect to one of the source electrode 122 and the drain electrode 123 through a contact hole provided at the first planarization layer 115a.

The second planarization layer 115b may be disposed on the connection electrode 135.

An emitting diode layer EDL may be placed on the second planarization layer 115b.

Hereinafter, a stack structure of the emitting diode layer EDL is described specifically.

A first emitting diode ED1 and a second emitting diode ED2 may be placed on the second planarization layer 115b in response to the first emission part EP1 and the second emission part EP2. Referring to FIG. 5, the first emitting diode ED1 may comprise a first anode electrode 142-1, a first emission layer 152-1, and a cathode electrode 160 that are stacked consecutively on the second planarization layer 115b. Additionally, the second emitting diode ED2 may comprise a second anode electrode 144-1, a second emission layer 154-1 and a cathode electrode 160 that are stacked consecutively on the second planarization layer 115b.

The first anode electrode 142-1 and the second anode electrode 144-1 made of an electrically conductive material of relatively high work function are formed on the second planarization layer 115b. The first anode electrode 142-1 is placed in the first emission part EP1, contacts the connection electrode 135 through a contact hole provided at the second planarization layer 115b and electrically connects to the first thin film transistor Tr1. Additionally, the second anode electrode 144-1 is placed in the second emission part EP2, contacts the connection electrode 135 through the contact hole provided at the second planarization layer 115b and electrically connects to the second thin film transistor Tr2.

Each of the first anode electrode 142-1 and the second anode electrode 144-1 may be formed of an electrically conductive transparent material such as indium tin oxide (ITO) or indium zinc oxide (IZO), but not limited thereto.

The display device 100 of one embodiment may be a top emission-type one where light of a plurality of emitting diodes ED1, ED2 is output in an opposite direction to the substrate SUB, and accordingly, each of the first anode electrode 142-1 and the second anode electrode 144-1 may further comprise a reflective electrode or a reflective layer that is formed of a metal material of high reflectance, under an electrically conductive transparent material. For example, the reflective electrode or the reflective layer may be made of an aluminum-palladium-copper (APC) alloy or silver (Ag) or aluminum (Al). At this time, each of the first anode electrode 142-1 and the second anode electrode 144-1 may have a triple-layer structure of ITO/APC/ITO or ITO/Ag/ITO or ITO/AI/ITO, but not limited thereto.

A bank 116 made of an insulation material is formed on the first anode electrode 142-1 and the second anode electrode 144-1. For example, the bank 116 may be made of polyimide resin, acryl resin or benzocyclobutene resin, but not limited thereto. In the present disclosure, the bank 116 may have a single-layer structure, but may also have a double-layer structure. That is, the bank 116 may have a double-layer structure that comprises a hydrophilic bank layer in the lower portion thereof and a hydrophobic bank layer in the upper portion thereof.

The bank 116 overlaps the edges of the first anode electrode 142-1 and the second anode electrode 144-1, and covers the edges of the first anode electrode 142-1 and the second anode electrode 144-1.

A first emission layer 152-1 and a second emission layer 154-1 are respectively formed on the first anode electrode 142-1 and the second anode electrode 144-1 exposed by the bank 116. The first emission layer 152-1 may generate light of luminance that corresponds to a difference between the voltages of the first anode electrode 142-1 and the cathode electrode 160, and the second emission layer 154-1 may generate light of luminance that corresponds to a difference between the voltages of the second anode electrode 144-1 and the cathode electrode 160. For example, the first emission layer 152-1 and the second emission layer 154-1 may comprise an emission material layer EML comprising a light emitting material. The light emitting material may comprise an organic material, an inorganic material or a hybrid material.

The first emission layer 152-1 and the second emission layer 154-1 may have a multi-layer structure. For example, the first emission layer 152-1 and the second emission layer 154-1 may further comprise at least one of a hole injection layer HIL, a hole transport layer HTL, an electron transport layer ETL, and an electron injection layer EIL.

Referring to FIG. 5, the first emission layer 152-1 of the first emitting diode ED1 and the second emission layer 154-1 of the second emitting diode ED2 may be respectively spaced However, the first emission layer 152-1 and the second emission layer 154-1 may also be disposed as a common layer in the first emitting diode ED1 and the second emitting diode ED2. For example, the first emission layer 152-1 on the first anode electrode 142-1, and the second emission layer 154-1 on the second anode electrode 144-1 may connect and be formed integrally.

A cathode electrode 160 made of an electrically conductive material of relatively low work function is substantially formed on the front surface of the substrate SUB, on the first emission layer 152-1 and the second emission layer 154-1. The cathode electrode 160 may be formed of aluminum or magnesium, or silver or an alloy thereof. The cathode electrode 160 may be relatively thin to transmit light from the first emission layer 152-1 and the second emission layer 154-1. Additionally, the cathode electrode 160 may be formed of an electrically conductive transparent material such as indium-gallium-oxide (IGO), but not limited thereto.

An encapsulation layer ENCAP may be placed on the emitting diode layer EDL described above. The encapsulation layer ENCAP prevents moisture or oxygen from infiltrating into the first emitting diode ED1 and the second emitting diode ED2 from the outside.

The encapsulation layer ENCAP may have a single-layer structure or a multi-layer structure. For example, the encapsulation layer ENCAP may comprise a first encapsulation layer 117a, a second encapsulation layer 117b and a third encapsulation layer 117c.

At this time, the first encapsulation layer 117a and the third encapsulation layer 117c may be comprised of an inorganic film, and the second encapsulation layer 117b may be comprised of an organic film. The second encapsulation layer 117b may be the thickest among the first encapsulation layer 117a, the second encapsulation layer 117b and the third encapsulation layer 117c, and serve as a planarization layer.

The first encapsulation layer 117a may be disposed on the first emitting diode ED1 and the second emitting diode ED2 and suppress the infiltration of moisture or oxygen. The first encapsulation layer 117a may be made of an inorganic material such as silicon oxide (SiOX), silicon nitride (SiNx), silicon oxynitride (SiNxOy) or aluminum oxide (AlyOz) and the like, but not limited thereto.

The second encapsulation layer 117b is disposed on the first encapsulation layer 117a and planarizes the surface thereof. Additionally, the second encapsulation layer 117b may cover foreign substances or particles that may be generated during manufacturing. The second encapsulation layer 117b may be made of an organic material, e.g., siliconoxycarbon (SiOxCz), acryl, or epoxy-based resin and the like, but not limited thereto.

The third encapsulation layer 117c may be disposed on the second encapsulation layer 117b, and like the first encapsulation layer 117a, suppress the infiltration of moisture or oxygen. At this time, the third encapsulation layer 117c and the first encapsulation layer 117a may be formed to seal the second encapsulation layer 117b. Accordingly, moisture or oxygen infiltrating into the first emitting diode ED1 and the second emitting diode ED2 may be reduced by the third encapsulation layer 117c more effectively. The third encapsulation layer 117c may be made of an inorganic material such as silicon oxide (SiOX), silicon nitride (SiNx), silicon oxynitride (SiNxOy) or aluminum oxide (AlyOz) and the like, but not limited thereto.

Though not illustrated in FIG. 5, a color filter may be disposed on the encapsulation layer ENCAP, but not limited thereto.

A touch sensing layer TSL may be disposed on the encapsulation layer ENCAP.

A touch buffer film 118a may be disposed on the encapsulation layer ENCAP, and a touch line 170 may be disposed on the touch buffer film 118a.

The touch line 170 may comprise a touch sensor metal 171 and a bridge metal 172 that are disposed on a different layer. A touch interlayer insulation film 118b may be disposed between the touch sensor metal 171 and the bridge metal 172.

For example, the touch sensor metal 171 may comprise a first touch sensor metal, a second touch sensor metal and a third touch sensor metal that are disposed to be adjacent to each other. The first touch sensor metal and the second touch sensor metal may electrically connect to each other, but in the case where the third touch sensor metal is between the first touch sensor metal and the second touch sensor metal, the first touch sensor metal and the second touch sensor metal may electrically connect to each other through the bridge metal 172 placed on a different layer. The bridge metal 172 may be insulated from the third touch sensor metal by the touch interlayer insulation film 118b.

At a time of formation of the touch sensing layer TSL, a liquid chemical used in processing (a developing solution or an etching solution and the like) or moisture from the outside, and the like may be generated. The touch buffer film 118a is disposed, and the touch sensing layer TSL is disposed on the touch buffer film 118a, to prevent a liquid chemical or moisture and the like at a time of manufacturing the touch sensing layer TSL from infiltrating into the emission layer comprising an organic material.

As described above, the touch buffer film 118a may prevent damage to the emission layer vulnerable to a liquid chemical or moisture. To prevent damage to the emission layer comprising an organic material vulnerable to high temperature, the touch buffer film 118a may be formed at a predetermined temperature (e.g., a low temperature of 100° C. or less) and formed of an organic insulation material having low permittivity of 1-3. For example, the touch buffer film 118a may be formed of an acryl, epoxy or siloxane-based material.

The display device 100 of the embodiment may be a flexible display device, and as the flexible display device bends, the encapsulation layer ENCAP may be damaged. At this time, the touch sensor metal 171 placed on the touch buffer film 118a may be broken. To prevent the encapsulation layer ENCAP from being damaged and the metal 171, 172 constituting the touch line 170 from being broken despite a bend of the flexible display device, the touch buffer film 118a of one embodiment may be made of an inorganic insulation material and provide planarization performance.

The touch sensing layer TSL comprises a light shielding pattern BM disposed on the touch buffer film 118a. The light shielding pattern BM is formed to correspond between the first to third sub pixels SP1, SP2, SP3 that are adjacent to each other or between the first emission part EP1 and the second emission part EP2. The light shielding pattern BM may be disposed to overlap the touch sensor metal 171 or the bridge metal 172.

The light shielding pattern BM may be a black matrix, and made of black resin or chromium oxide and the like. On the contrary, the light shielding pattern BM may be made of metal. Additionally, since the touch sensor metal 171 or the bridge metal 172 may perform a light shielding function, the light shielding pattern BM may be omitted, when necessary.

A lens layer LL may be disposed on the touch sensing layer TSL.

A first lens 182-1 and a second lens 184-1 are disposed in an area corresponding to the first emission part EP1 and the second emission part EP2. The first lens 182-1 and the second lens 184-1 may be respectively disposed to correspond to an opening formed by the light shielding pattern BM. Accordingly, light generated by the first emitting diode ED1 may be emitted through the first lens 182-1 of a corresponding sub pixel, and light generated by the second emitting diode ED2 of each sub pixel may be emitted through the second lens 184-1 of a corresponding sub pixel.

The first lens 182-1 and the second lens 184-1 may limit a viewing angle by refracting light in a specific direction. That is, the first lens 182-1 is disposed in the first emission part EP1 and refracts light from the first emitting diode ED1 in a specific direction. Additionally, the second lens 184-1 is disposed in the second emission part EP2 and refracts light from the second emitting diode ED2 in a specific direction.

For example, the first lens 182-1, as a half-spherical lens, has a semicircle-shaped cross section on a planar surface. At this time, a direction in which light emitted from the first emitting diode ED1 of the first sub pixel SP1 proceeds is limited to a first direction and a second direction. That is, in the case where the first emission part EP1 displays an image, a narrow field of view mode in which a limited viewing angle is provided may be embodied.

The second lens 184-1, as a half-cylindrical lens, has a rectangle-shaped cross section in one direction, and has a semicircle-shaped cross section in another direction. The half-cylindrical lens may not limit a viewing angle in one direction, and may limit a viewing angle in another direction.

Referring to FIG. 4, the second lens 184-1 may have a half-cylindrical shape that is elongated in the X-axis direction. Specifically, the second lens 184-1 may have a rectangle-shaped cross section in the X-axis direction and has a semicircle-shaped cross section in the Y-axis direction. Accordingly, the second lens 184-1 limits a viewing angle of the Y-axis direction, and the second lens 184-1 does not limit a viewing angle of the X-axis direction. For example, the second emission part EP2 provided with the half-cylindrical second lens 184-1 may have a narrow viewing angle of 30 degrees or less in the Y-axis direction, and have a wide viewing angle of 60 degrees or greater in the X-axis direction.

Referring to FIG. 5, a lens protective layer 119 is provided on the first lens 182-1 and the second lens 184-1 and protects the first lens 182-1 and the second lens 184-1. The lens protective layer 119 may be made of an organic insulation material, and have a planar upper surface. Additionally, the refractive index of the lens protective layer 119 may be less than the refractive index of the first lens 182-1 and the refractive index of the second lens 184-1.

In an example, the lens protective layer 119 may be made of photo acryl or benzocyclobutene (BCB), polyimide (PI), or polyamide (PA), and not limited thereto.

Further, though not illustrated in FIG. 5, a cover glass may be attached by an adhesive layer. The adhesive layer may attach each of the components of the display device 100 to each other, and for example, may be formed by using an optically clear adhesive for a display such as a pressure sensitive adhesive, an optical clear adhesive (OCA), an optical clear resin (OCR) and the like, but not limited thereto. The cover glass may protect the components of the display device 100 from an external impact and prevent occurrence of damage such as a scratch and the like.

Further, in FIG. 5, a cross-sectional view of the first sub pixel SP1 is only illustrated, but the structures of the second sub pixel SP2 and the third sub pixel SP3 are substantially the same as the structure of the first sub pixel SP1 except that in the case of a second sub pixel SP2 and a third sub pixel SP3, the first anode electrode 142-2 and the second anode electrode 144-2 of the second sub pixel SP2, and the first anode electrode 142-3 and the second anode electrode 144-3 of the third sub pixel SP3 connect to a pixel circuit in a row where a corresponding pixel is disposed.

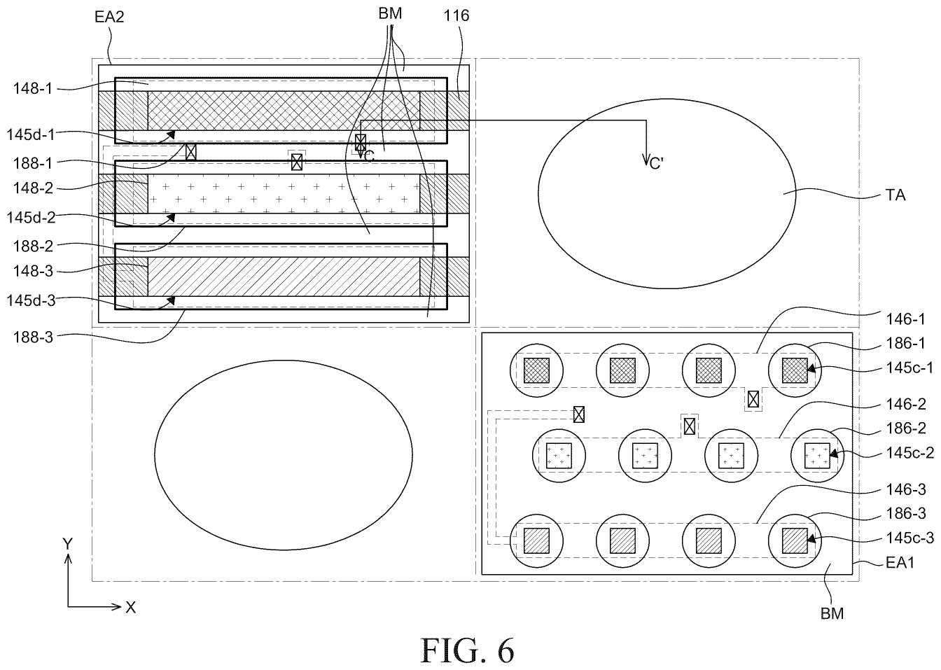

Hereinafter, the structure of the optical area of the display device of one embodiment is specifically described with reference to FIGS. 6-8C. Hereinafter, a display area DA comprising a normal area NA and a first optical area DA1 in the display panel DP of the display device 100 (i.e., FIGS. 1A and 1B) is described as an example, for convenience of description, but description of the first optical area DA1 may be applied to the second optical area DA2 in the same way.

FIG. 6 is a plan view of a pixel of a first optical area of the display device of one embodiment.

In FIG. 6, a third opening 145c-1, 145c-2, 145c-3, a fourth opening 145d-1, 145d-2, 145d-3, a third lens 186-1, 186-2, 186-3 and a fourth lens 188-1, 188-2, 188-3 at each of the first to third sub pixels SP1, SP2, SP3 in the first optical area DA1 are illustrated only.

As described with reference to FIG. 3, the first optical area DA1 may comprise an emission area EA and a transmittance area TA. At this time, the emission area EA of the first optical area DA1 comprises a first emission area EA1 and a second emission area EA2. The first emission area EA1 is an emission area for embodying a narrow viewing angle in the first optical area DA1, and the second emission area EA2 is an emission area for embodying a wide viewing angle in the first optical area DA1.

Referring to FIGS. 3 and 6, the first emission area EA1 and the transmittance area TA are arranged alternately in the X direction and the Y direction. Additionally, the second emission area EA2 and the transmittance area TA are arranged alternately in the X direction and the Y direction. Accordingly, the first emission area EA1 and the second emission area EA2 may be continuously arranged in a diagonal direction with respect to the X direction and the Y direction, but not limited in the present disclosure, and the first emission area EA1, the second emission area EA2 and the transmittance area TA may be arranged in various ways.

Like the emission area of the normal area NA, each of the first emission area EA1 and the second emission area EA2 comprises first to third sub pixels SP1, SP2, SP3, and the first sub pixel SP1 may be a red sub pixel, the second sub pixel SP2 may be a green sub pixel, and the third sub pixel SP3 may be a blue sub pixel.

Ordinarily, the first to third sub pixels SP1, SP2, SP3 included in the emission area of the normal area NA, and the first to third sub pixels SP1, SP2, SP3 included in the first emission area EA1 and the second emission area EA2 of the first optical area DA1 are configured to emit light of the same color, but not limited thereto, and may be configured in a different way depending on design. Hereinafter, the first to third sub pixels SP1, SP2, SP3 of the normal area NA and the first optical area DA1, for example, are configured to emit light of the same color, for convenience of description.

Referring to FIG. 6, first to third sub pixels SP1, SP2, SP3 are disposed in the first emission area EA1. The first to third sub pixels SP1, SP2, SP3 in the first emission area EA1 respectively comprise a third anode electrode 146-1, 146-2, 146-3. Each third anode electrode 146-1, 146-2, 146-3 connects to a third thin film transistor Tr3 disposed in each of the first to third sub pixels SP1, SP2, SP3.

At each of the first to third sub pixels SP1, SP2, SP3 in the first emission area EA1, at least one third opening 145c-1, 145c-2, 145c-3 is provided on the third anode electrode 146-1, 146-2, 146-3. On an X-Y plan view, each of the third openings 145c-1, 145c-2, 145c-3 may have a shape in which a length in the X direction is substantially the same as a length in the Y-direction. The shape and size of the third opening 145c-1, 145c-2, 145c-3 formed in the first emission area EA1 may be the same as the shape and size of the first opening 145a-1, 145a-2, 145a-3 in the normal area.

In FIG. 6, four third openings 145c-1, 145c-2, 145c-3 may be disposed respectively on the first to third sub pixels SP1, SP2, SP3 in the first emission area EA1. Specifically, four third openings 145c-1 in the first sub pixel may be disposed in the X direction and spaced by a predetermined distance. Four third openings 145c-2 of the second sub pixel may be spaced in the Y direction with respect to the third openings 145c-1 of the first sub pixel. Similarly, four third openings 145c-3 in the third sub pixel may be spaced in the Y direction with respect to the third openings 145c-2 of the second sub pixel.

In response to each of the third openings 145c-1, 145c-2, 145c-3, a half-spherical third lens 186-1, 186-2, 186-3 is disposed. The third lens 186-1, 186-2, 186-3 formed in the first emission area EA1 may have the same shape and size as the first lens 182-1, 182-2, 182-3 in the normal area. Each of the third lenses 186-1, 186-2, 186-3 is disposed to cover each of the third openings 145c-1, 145c-2, 145c-3. On an X-Y planar surface, the surface area of each of the third lenses 186-1, 186-2, 186-3 may be greater than the surface area of each of the third openings 145c-1, 145c-2, 145c-3.

Like the first emission area EA1, first to third sub pixels SP1, SP2, SP3 are also disposed in the second emission area EA2. The first to third sub pixels SP1, SP2, SP3 in the second emission area EA2 respectively comprise a fourth anode electrode 148-1, 148-2, 148-3. Each fourth anode electrode 148-1, 148-2, 148-3 connects to a fourth thin film transistor Tr4 disposed in each of the first to third sub pixels SP1, SP2, SP3.

At each of the first to third sub pixels SP1, SP2, SP3 in the second emission area EA2, one fourth opening 145d-1, 145d-2, 145d-3 is provided on the fourth anode electrode 148-1, 148-2, 148-3. On an X-Y plan view, each of the fourth openings 145d-1, 145d-2, 145d-3 may have a long polygonal shape in which a length in the X direction is greater than a length in the Y direction. The shape and size of the fourth opening 145d-1, 145d-2, 145d-3 formed in the second emission area EA2 may be the same as the shape and size of the second opening 145b-1, 145b-2, 145b-3 in the normal area.

In response to each of the fourth openings 145d-1, 145d-2, 145d-3, a half-cylindrical fourth lens 188-1, 188-2, 188-3 is disposed. The fourth lens 188-1, 188-2, 188-3 formed in the second emission area EA2 may have the same shape and size as the second lens 184-1, 184-2, 184-3 in the normal area. Each of the fourth lenses 188-1, 188-2, 188-3 is disposed to cover each of the fourth openings 145d-1, 145d-2, 145d-3. On an X-Y planar surface, the surface area of each of the fourth lenses 188-1, 188-2, 188-3 may be greater than the surface area of each of the fourth openings 145d-1, 145d-2, 145d-3.

On a planar surface, the third anode electrode 146-1, 146-2, 146-3 and the fourth anode electrode 148-1, 148-2, 148-3 in the first emission area EA1 and the second emission area EA2 of the first optical area DA1 may have the same shape or a similar shape. However, in the first emission area EA1 and the second emission area EA2 of the first optical area DA1, the light shielding pattern BM may have a different shape on a planar surface. Accordingly, the shapes of the openings respectively formed by the light shielding pattern BM may differ.

In particular, the light shielding pattern BM formed in the second emission area EA2 may have a shape different from the shape of the light shielding pattern BM formed in the normal area NA. Referring to FIGS. 4 and 5, the light shielding pattern BM formed in the emission area of the normal area NA is shaped to surround the emission area of each sub pixel. For example, the light shielding pattern BM may form an opening that is wider than the first emission part EP1 and the second emission part EP2 to surround the first emission part EP1 of the first emitting diode ED1 and the second emission part EP2 of the second emitting diode ED2. Referring to FIG. 4, the light shielding pattern BM overlaps the first anode and the second anode, and is formed in both the X direction and the Y direction.

However, the light shielding pattern BM formed in the second emission area EA2 has a structure that is open in one direction without surrounding the emission area of each sub pixel. For example, referring to FIG. 6, the light shielding pattern BM is not disposed in the first sub pixel of the second emission area EA2 in the X-axis direction while being disposed around the emission part in the Y-axis direction. Accordingly, both sides of the light shielding pattern BM are open in the X-axis direction around the fourth anode. Accordingly, on a planar surface, the bank 116 defining the emission part of the fourth emitting diode may be exposed around the fourth anode in the X-axis direction and viewed. Accordingly, the fourth opening 145d-1, 145d-2, 145d-3 of the second emission area EA2 defined by the light shielding pattern BM may be open totally in the X-axis direction in the second emission area EA2 and have a greater surface area than the second opening 145b-1, 145b-2, 145b-3 of the normal area NA. As illustrated in FIG. 6, since the half-cylindrical fourth lens 188-1, 188-2, 188-3 disposed on the fourth opening 145d-1, 145d-2, 145d-3 limits a viewing angle in the Y-axis direction and does not limit a viewing angle in the X-axis direction, the limitation of a viewing angle in the X-axis direction by the light shielding pattern BM may be resolved, at a time when a wide viewing angle is embodied, in the case where the light shielding pattern BM is structured to be open in the X-axis direction, and a wider viewing angle may be provided in the X-axis direction.

As described above, in the case of a display device of one embodiment, the half-spherical third lens 186-1, 186-2, 186-3 is provided in response to the third anode electrode 146-1, 146-2, 146-3, and the half-cylindrical fourth lens 188-1, 188-2, 188-3 is provided in response to the fourth anode electrode 148-1, 148-2, 148-3, in response to the third anode electrode 146-1, 146-2, 146-3, even in the first optical area comprising the transmittance area TA, to limit a viewing angle. At this time, a direction in which the third lens 186-1, 186-2, 186-3 limits a viewing angle may differ from a direction in which the fourth lens 188-1, 188-2, 188-3 limits a viewing angle, and based on selective driving, a wide viewing angle and a narrow viewing angle may be embodied.

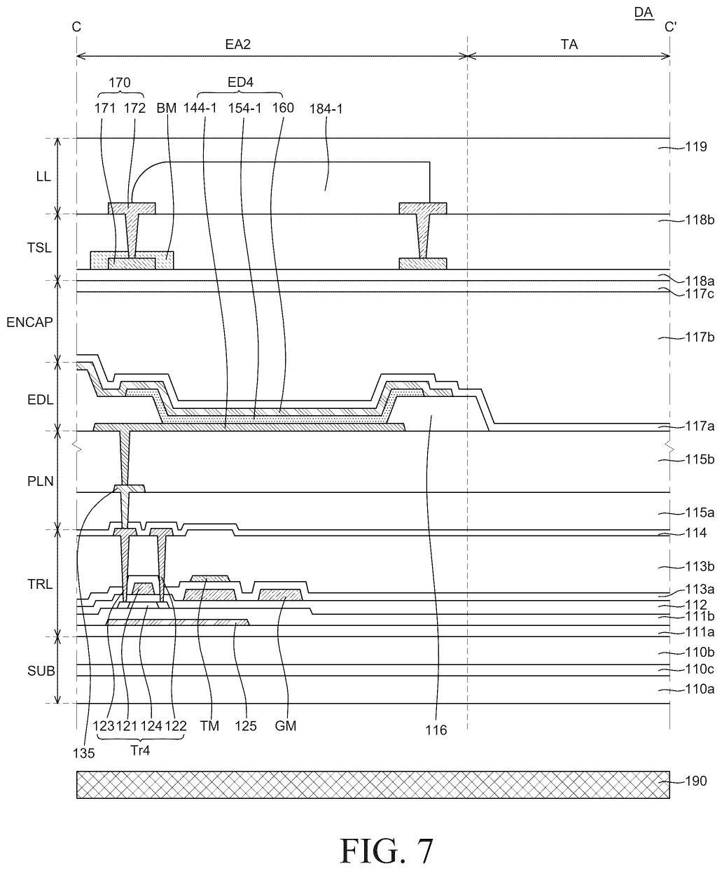

Hereinafter, a fourth emitting diode ED4 of the first optical area DA1 is specifically described with reference to FIG. 7.

FIG. 7 is a cross-sectional view along C-C′ of FIG. 6. FIG. 7 is a cross-sectional view of a first sub pixel SP1 and a transmittance area TA of the second emission area EA2 of the first optical area DA1.

Each of the second emission area EA2 and the transmittance area TA of the first optical area DA1 may basically comprise a substrate SUB, a transistor layer TRL, a planarization layer PLN, an emitting diode layer EDL, an encapsulation layer ENCAP, a touch sensing layer TSL, and a protective layer 119. At this time, an optical electronic device 190 may be disposed under the substrate SUB in the first optical area DA1.

The substrate SUB, the transistor layer TRL, the planarization layer PLN, the emitting diode layer EDL, the encapsulation layer ENCAP, the touch sensing layer TSL, and the lens layer LL included in the first optical area DA1 are substantially the same as the components of identical reference symbols disposed in the normal area NA that is described above with reference to FIG. 5. Accordingly, the identical components are not described.

As described above, each sub pixel in the second emission area EA2 of the first optical area DA1 has a light shielding pattern BM shape different from that in the normal area NA. Accordingly, since the light shielding pattern BM is open in the X-axis direction on a planar surface, unlike the normal area NA, the second emission area EA2 has no light shielding pattern BM in a partial area thereof. Referring to FIGS. 6 and 7 together, the light shielding pattern BM may not be disposed on a partial touch electrode. Accordingly, the end of the bank may be exposed in the X-axis direction, while being covered by the light shielding pattern in the Y-axis direction.

Hereinafter, the transmittance area TA disposed in the first optical area DA1 is described.

The substrate SUB and various types of insulation films 111a, 111b, 112, 113a, 113b, 114, 115a, 115b, 117a, 117b, 117c, PAC disposed in the second emission area EA2 of the first optical area DA1 may also be disposed in the transmittance area TA of the first optical area DA1 in the same way.

However, except for the insulation materials disposed in the second emission area EA2 of the first optical area DA1, a material layer having electric or opaque properties may not be disposed in the transmittance area TA of the first optical area DA1.

For example, the bank 116 may not be disposed in the transmittance area TA. In the case where the bank 116 is a black bank having a black color or a colored bank, the bank 116 is not disposed in an area except for a partial area close to the emission area EA1, EA2, in the transmittance area TA.

Additionally, a metal material layer 135, 131, GM, TM, 132, 133, 125 and a semiconductor layer 134 in relation to a transistor are not disposed in the transmittance area TA. The anode included in the emitting diode ED may not be disposed in the transmittance area TA, the cathode 160 may not be disposed in an area except for a partial area close to the emission area EA1, EA2, in the transmittance area TA, and the emission layer may be disposed in the transmittance area TA or may not. The touch sensor metal 171 and the bridge metal 172 included in the touch sensor are not disposed in the transmittance area TA.

Since the transmittance area TA in the first optical area DA1 overlaps the optical electronic device 190, a transmittance ratio of a transmittance area TA where the optical electronic device 190 can operate normally needs to be secured. In one embodiment, to secure the transmittance ratio of the transmittance area TA, a cathode 160 is not disposed in the transmittance area TA.

To this end, a deposition prevention layer (not illustrated) made of an organic material may be disposed on the second planarization layer 115b and the emission layer of the transmittance area TA. The deposition prevention layer may perform the function of preventing the deposition of the cathode 160. Since during formation of a cathode electrode, a cathode electrode material may not be deposited on the deposition prevention layer, the cathode electrode may be selectively formed on the substrate SUB. For example, the deposition prevention layer may be deposited by using a mask (a fine metal mask; FMM) to correspond to the transmittance area TA. Specifically, the FMM is placed in such a way that the transmittance area TA is exposed, and then the deposition prevention layer may be formed. In the case where the cathode 160 is deposited after the deposition prevention layer is disposed on the emission layer of the transmittance area TA, since adhesion between the deposition prevention layer and a layer disposed thereon is low, the cathode 160 may not be deposited in an area where the deposition prevention layer is disposed.

In the display device 100 of one embodiment, an optical area DA1, DA2 comprising the transmittance area TA is provided to dispose a variety of optical electronic devices 190 under the display panel. At this time, a plurality of lenses may be used to embody a wide viewing angle where a wide viewing angle is ensured based on the user's selective driving mode and a narrow viewing angle where a viewing angle is limited to enhance security. However, in the case where a viewing angle is limited by using a lens, the optical area comprising a transmittance area may have a lower opening ratio of a pixel than the normal area comprising no transmittance area, and accordingly, the lifespan of the pixel may deteriorate. As shown in FIG. 3, in the case where the pixel arrangement structure of the normal area NA is applied to the optical area DA1, DA2 comprising the transmittance area TA by using a lens for limiting a viewing angle, since the transmittance area TA needs to be secured, the opening ratios of sub pixels in the optical area DA1, DA2 are likely to deteriorate significantly.

However, in the display device 100 of one embodiment, the second emission area EA2 providing a wide viewing angle, and the first emission area EA1 providing a narrow viewing angle, in the optical area DA1, DA2, are disposed in a separate manner, to increase an opening ratio per unit surface area significantly. As the opening ratios of sub pixels increase in the optical area DA1, DA2, current density in the emitting diode of each sub pixel may decrease, and accordingly, the lifespan of the element may increase.

For example, in the case where a comparative example of application of the sub pixel arrangement structure of the normal area in the optical area is compared with an embodiment of application of the sub pixel arrangement structure in the optical area illustrated in FIG. 3, while the transmittance ratios in the optical area are the same, the opening ratios of sub pixels may improve, and the current density of each sub pixel may decrease by about 50%. Accordingly, the lifespan of a sub pixel in the optical area may improve.

Hereinafter, the configuration and driving method of a pixel circuit of the plurality of sub pixels are specifically described.

Switch elements constituting each of the plurality of sub pixels may be embodied as a transistor of a n-type or p-type MOSFET (Metal Oxide Semiconductor Field Effect Transistor) structure. In an embodiment provided hereinafter, a p-type transistor is provided as an example, but not limited thereto.

Additionally, the transistor is a three-electrode element comprising a gate electrode, a source electrode and a drain electrode. The source electrode is an electrode providing a carrier to the transistor. The carrier in the transistor starts to flow from the source electrode. The drain electrode is an electrode where the carrier goes out from the transistor. That is, in the MOSFET, the carrier flows from the source electrode to the drain electrode. In the case of a n-type MOSFET (NMOS), since the carrier is an electron, the voltage of the source electrode is less than that of the drain electrode, so that the electron may flow from the source electrode to the drain electrode. Since the electron flows from the source electrode to the drain electrode in the n-type MOSFET, the current flows from the drain electrode to the source electrode. In the case of a p-type MOSFET (PMOS), since the carrier is a hole, the voltage of the source electrode is greater than that of the drain electrode, so that the hole may flow from the source electrode to the drain electrode. Since the hole flow from the source electrode to the drain electrode in the p-type MOSFET, current flows from the source electrode to the drain electrode. It is noteworthy that the source electrode and the drain electrode of the MOSFET are not fixed. For example, the source electrode and the drain electrode of the MOSFET may change depending on a supplied voltage. In an embodiment described hereinafter, the subject matter of the present disclosure is not limited by the source electrode and the drain electrode of the transistor.

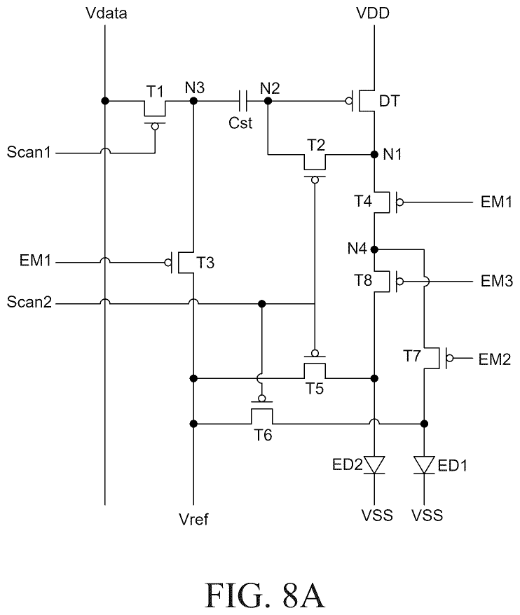

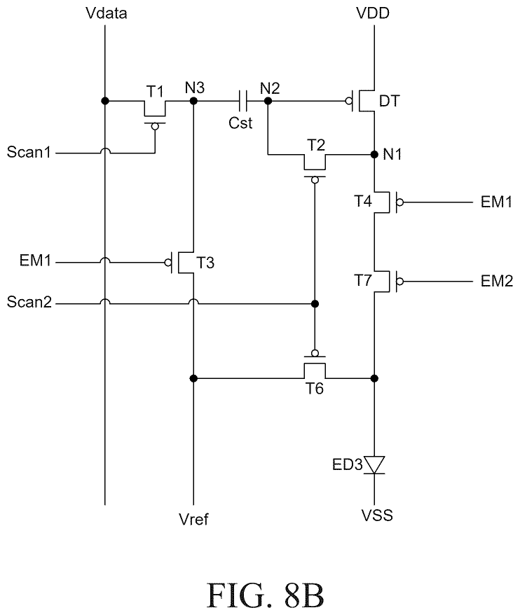

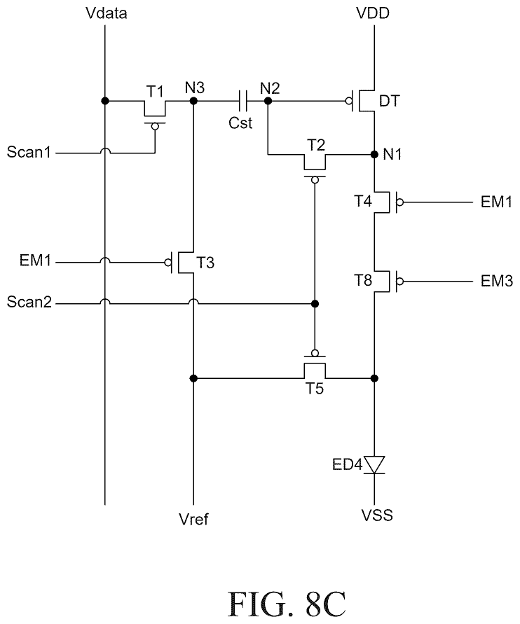

FIG. 8A is a circuit diagram of a sub pixel in the normal area of the display device of one embodiment.

Each of a plurality of sub pixels SP1, SP2, SP3 comprises a first emitting diode ED1, a second emitting diode ED2, a driving transistor DT, first to eighth transistors T1-T8 and a capacitor Cst.

Each of the first emitting diode ED1 and the second emitting diode ED2 emits light by driving current supplied from the driving transistor DT. Specifically, an anode electrode of the first emitting diode ED1 connects to a seventh transistor T7, and a cathode electrode of the first emitting diode ED1 connects to an input terminal of a low potential driving voltage VSS. Additionally, an anode electrode of the second emitting diode ED2 connects to an eighth transistor T8, and a cathode electrode of the second emitting diode ED2 connects to an input terminal of a low potential driving voltage VSS.

The driving transistor DT controls driving current supplied to each first emitting diode ED1, based on a voltage Vsg between a source and a gate thereof. Additionally, the source electrode of the driving transistor DT connects to an input terminal of a high potential driving voltage VDD, the gate electrode connects to a second node N2, and the drain electrode connects to a first node N1.

The first transistor T1 supplies a data voltage Vdata supplied from a data line to a third node N3. The first transistor T1 comprises a source electrode connecting to a data line, a drain electrode connecting to a third node N3, and a gate electrode connecting to a first scan signal line transmitting a first scan signal Scan1. Accordingly, the first transistor T1 supplies a data voltage Vdata supplied from the data line to the third node N3, in response to a first scan signal Scan1 of a low level that is a turn-on level.

The second transistor T2 diode-connects the gate electrode and the drain electrode of the driving transistor DT. The second transistor T2 comprises a drain electrode connecting to a second node N2, a source electrode connecting to a first node N1, and a gate electrode connecting to a second scan signal line transmitting a second scan signal Scan2. Accordingly, the second transistor T2 diode-connects the gate electrode and the drain electrode of the driving transistor DT, in response to a second scan signal Scan2 of a low level that is a turn-on level.

A third transistor T3 supplies a reference voltage Vref to a third node N3. The third transistor T3 comprises a source electrode connecting to a reference voltage line transmitting a reference voltage Vref, a drain electrode connecting to a third node N3, and a gate electrode connecting to a first emission signal line transmitting a first emission signal EM1. Accordingly, the third transistor T3 supplies a reference voltage Vref to the third node N3 in response to a first emission signal EM1 of a low level that is a turn-on level.

A fourth transistor T4 forms a current path between the driving transistor DT and the first emitting diode ED1 or the second emitting diode ED2. The fourth transistor T4 comprises a source electrode connecting to a first node N1, a drain electrode connecting to a fourth node N4 and a gate electrode connecting to a first emission signal line transmitting a first emission signal EM1. The fourth transistor T4 forms a current path at the first node N1 and the fourth node N4 of the fourth transistor T4 in response to a first emission signal EM1. Accordingly, the fourth transistor T4 forms a current path between the driving transistor DT and the first emitting diode ED1 or between the driving transistor DT and the second emitting diode ED2, in response to a first emission signal EM1 of a low level that is a turn-on level, depending on the turn-on or turn-off of a seventh transistor T7 and an eighth transistor T8 described below.

A fifth transistor T5 supplies a reference voltage Vref to an anode electrode of the second emitting diode ED2. The fifth transistor T5 may comprise a source electrode connecting to a reference voltage line supplying a reference voltage Vref, a drain electrode connecting to the anode electrode of the second emitting diode ED2, and a gate electrode connecting to a second scan signal line to which a second scan signal Scan2 is supplied. The fifth transistor T5 may be turned on or turned off by a second scan signal Scan2. Accordingly, the fifth transistor T5 may supply a reference voltage Vref to the anode electrode of the second emitting diode ED2 in response to a second scan signal Scan2 of a low level that is a turn-on level.

A sixth transistor T6 supplies a reference voltage Vref to an anode electrode of the first emitting diode ED1. The sixth transistor T6 comprises a source electrode connecting to a reference voltage line supplying a reference voltage Vref, a drain electrode connecting to the anode electrode of the first emitting diode ED1, and a gate electrode connecting to a second scan signal line transmitting a second scan signal Scan2. The sixth transistor T6 may be turned on or turned off by a second scan signal Scan2. Accordingly, the sixth transistor T6 may supply a reference voltage Vref to the anode electrode of the first emitting diode ED1 in response to a second scan signal Scan2 of a low level that is a turn-on level.

A seventh transistor T7 forms a current path between the driving transistor DT and the first emitting diode ED1. The seventh transistor T7 comprises a source electrode connecting to a fourth node N4, a drain electrode connecting to an anode electrode of the first emitting diode ED1 and a gate electrode connecting to a second emission signal line transmitting a second emission signal EM2. The seventh transistor T7 forms a current path between the fourth node N4 as a source electrode of the seventh transistor T7 and the first emitting diode ED1, in response to a second emission signal EM2. Accordingly, the seventh transistor T7 forms a current path between the driving transistor DT and the first emitting diode ED1, in response to a second emission signal EM2 of a low level that is a turn-on level.

An eighth transistor T8 forms a current path between the driving transistor DT and the second emitting diode ED2. The eighth transistor T8 comprises a source electrode connecting to a fourth node N4, a drain electrode connecting to an anode electrode of the second emitting diode ED2 and a gate electrode connecting to a third emission signal line transmitting a third emission signal EM3. The eighth transistor T8 forms a current path between the fourth node N4 as a source electrode of the eighth transistor T8 and the second emitting diode ED2, in response to a third emission signal EM3. Accordingly, the eighth transistor T8 forms a current path between the driving transistor DT and the second emitting diode ED2, in response to a third emission signal EM3 of a low level that is a turn-on level.

A capacitor Cst comprises a first electrode connecting to the second node N2 and a second electrode connecting to the third node N3. That is, one electrode of the capacitor Cst connects to the gate electrode of the driving transistor DT, and another electrode of the capacitor Cst connects to the first transistor T1 and the third transistor T3.

FIG. 8B is a circuit diagram of a sub pixel of a first emission area in the first optical area of the display device of one embodiment.

Each of a plurality of sub pixels SP1, SP2, SP3 comprises a third emitting diode ED3, a driving transistor DT, first to fourth transistors T1-T4, sixth to seventh transistors T6-T7 and a capacitor Cst.

An anode electrode of the third emitting diode ED3 connects to the seventh transistor T7, and a cathode electrode of the third emitting diode ED3 connects to an input terminal a low potential driving voltage VSS.

The driving transistor DT controls driving current that is supplied to the third emitting diode ED3 depending on a voltage Vsg between a source and a gate thereof. Additionally, the source electrode of the driving transistor DT connects to an input terminal of a high potential driving voltage VDD, the gate electrode connects to the second node N2, and the drain electrode connects to the first node N1.

A first transistor T1 supplies a data voltage Vdata supplied from a data line to a third node N3. The first transistor T1 comprises a source electrode connecting to a data line, a drain electrode connecting to a third node N3, and a gate electrode connecting to a first scan signal line transmitting a first scan signal Scan1. Accordingly, the first transistor T1 supplies a data voltage Vdata supplied from the data line to the third node N3 in response to a first scan signal Scan1 of a low level that is a turn-on level.

A second transistor T2 diode-connects the gate electrode and the drain electrode of the driving transistor DT. The second transistor T2 comprises a drain electrode connecting to a second node N2, a source electrode connecting to a first node N1, and a gate electrode connecting to a second scan signal line transmitting a second scan signal Scan2. Accordingly, the second transistor T2 diode-connects the gate electrode and the drain electrode of the driving transistor DT, in response to a second scan signal Scan2 of a low level that is a turn-on level.

A third transistor T3 supplies a reference voltage Vref to a third node N3. The third transistor T3 comprises a source electrode connecting to a reference voltage line transmitting a reference voltage Vref, a drain electrode connecting to a third node N3, and a gate electrode connecting to a first emission signal line transmitting a first emission signal EM1. Accordingly, the third transistor T3 supplies a reference voltage Vref to the third node N3 in response to a first emission signal EM1 of a low level that is a turn-on level.

A fourth transistor T4 forms a current path between the driving transistor DT and the third emitting diode ED3. The fourth transistor T4 comprises a source electrode connecting to a first node N1, a drain electrode connecting to a seventh transistor T7 and a gate electrode connecting to a first emission signal line transmitting a first emission signal EM1. The fourth transistor T4 forms a current path at the first node N1 of the fourth transistor T4 and the seventh transistor T7 in response to a first emission signal EM1. Accordingly, the fourth transistor T4 forms a current path between the driving transistor DT and the third emitting diode ED3, in response to a first emission signal EM1 of a low level that is a turn-on level, depending on the turn-on or turn-off of the seventh transistor T7.

A sixth transistor T6 supplies a reference voltage Vref to an anode electrode of the third emitting diode ED3. The sixth transistor T6 comprises a source electrode connecting to a reference voltage line supplying a reference voltage Vref, a drain electrode connecting to an anode electrode of the third emitting diode ED3, and a gate electrode connecting to a second scan signal line transmitting a second scan signal Scan2. The sixth transistor T6 may be turned on or turned off by a second scan signal Scan2. Accordingly, the sixth transistor T6 may supply a reference voltage Vref to the anode electrode of the third emitting diode ED3 in response to a second scan signal Scan2 of a low level that is a turn-on level.

A seventh transistor T7 forms a current path between the driving transistor DT and the third emitting diode ED3. The seventh transistor T7 comprises a source electrode connecting to a fourth transistor T4, a drain electrode connecting to an anode electrode of the third emitting diode ED3 and a gate electrode connecting to a second emission signal line transmitting a second emission signal EM2. The seventh transistor T7 forms a current path between the fourth transistor T4 and the third emitting diode ED3, in response to a second emission signal EM2. Accordingly, the seventh transistor T7 forms a current path between the driving transistor DT and the third emitting diode ED3, in response to a second emission signal EM2 of a low level that is a turn-on level.

A capacitor Cst comprises a first electrode connecting to the second node N2 and a second electrode connecting to the third node N3. That is, one electrode of the capacitor Cst connects to the gate electrode of the driving transistor DT, and another electrode of a capacitor Cst connects to the first transistor T1 and the third transistor T3.

FIG. 8C is a circuit diagram of a sub pixel of a second emission area in the first optical area of the display device of one embodiment.

Each of a plurality of sub pixels SP1, SP2, SP3 comprises a fourth emitting diode ED4, a driving transistor DT, first to fifth transistors T1-T5, an eighth transistor T8 and a capacitor Cst.

An anode electrode of the fourth emitting diode ED4 connects to the fourth transistor T4, and a cathode electrode of the fourth emitting diode ED4 connects to an input terminal of a low potential driving voltage VSS.

The driving transistor DT controls driving current that is supplied to the fourth emitting diode ED4 depending on a voltage Vsg between a source and a gate thereof. Additionally, the source electrode of the driving transistor DT connects to an input terminal of a high potential driving voltage VDD, the gate electrode connects to the second node N2, and the drain electrode connects to the first node N1.

A first transistor T1 supplies a data voltage Vdata supplied from a data line to a third node N3. The first transistor T1 comprises a source electrode connecting to a data line, a drain electrode connecting to a third node N3, and a gate electrode connecting to a first scan signal line transmitting a first scan signal Scan1. Accordingly, the first transistor T1 supplies a data voltage Vdata supplied from the data line to the third node N3 in response to a first scan signal Scan1 of a low level that is a turn-on level.

A second transistor T2 diode-connects the gate electrode and the drain electrode of the driving transistor DT. The second transistor T2 comprises a drain electrode connecting to a second node N2, a source electrode connecting to a first node N1, and a gate electrode connecting to a second scan signal line transmitting a second scan signal Scan2. Accordingly, the second transistor T2 diode-connects the gate electrode and the drain electrode of the driving transistor DT, in response to a second scan signal Scan2 of a low level that is a turn-on level.

A third transistor T3 supplies a reference voltage Vref to a third node N3. The third transistor T3 comprises a source electrode connecting to a reference voltage line transmitting a reference voltage Vref, a drain electrode connecting to a third node N3, and a gate electrode connecting to a first emission signal line transmitting a first emission signal EM1. Accordingly, the third transistor T3 supplies a reference voltage Vref to the third node N3 in response to a first emission signal EM1 of a low level that is a turn-on level.

A fourth transistor T4 forms a current path between the driving transistor DT and the fourth emitting diode ED4. The fourth transistor T4 comprises a source electrode connecting to a first node N1, a drain electrode connecting to an eighth transistor T8 and a gate electrode connecting to a first emission signal line transmitting a first emission signal EM1. The fourth transistor T4 forms a current path at the first node N1 of the fourth transistor T4 and the eighth transistor T8 in response to a first emission signal EM1. Accordingly, the fourth transistor T4 forms a current path between the driving transistor DT and the fourth emitting diode ED4, in response to a first emission signal EM1 of a low level that is a turn-on level, depending on the turn-on or turn-off of the eighth transistor T8.

A fifth transistor T5 supplies a reference voltage Vref to an anode electrode of the fourth emitting diode ED4. The fifth transistor T5 may comprise a source electrode connecting to a reference voltage line supplying a reference voltage Vref, a drain electrode connecting to an anode electrode of the fourth emitting diode ED4, and a gate electrode connecting to a second scan signal line to which a second scan signal Scan2 is supplied. The fifth transistor T5 may be turned on or turned off by a second scan signal Scan2. Accordingly, the fifth transistor T5 may supply a reference voltage Vref to the anode electrode of the fourth emitting diode ED4 in response to a second scan signal Scan2 of a low level that is a turn-on level.

An eighth transistor T8 forms a current path between the driving transistor DT and the fourth emitting diode ED4. The eighth transistor T8 comprises a source electrode connecting to the fourth transistor T4, a drain electrode connecting to an anode electrode of the fourth emitting diode ED4 and a gate electrode connecting to a third emission signal line transmitting a third emission signal EM3. The eighth transistor T8 forms a current path between the fourth transistor T4 and the fourth emitting diode ED4, in response to a third emission signal EM3. Accordingly, the eighth transistor T8 forms a current path between the driving transistor DT and the fourth emitting diode ED4, in response to a third emission signal EM3 of a low level that is a turn-on level.

A capacitor Cst comprises a first electrode connecting to the second node N2 and a second electrode connecting to the third node N3. That is, one electrode of the capacitor Cst connects to the gate electrode of the driving transistor DT, and another electrode of the capacitor Cst connects to the first transistor T1 and the third transistor T3.

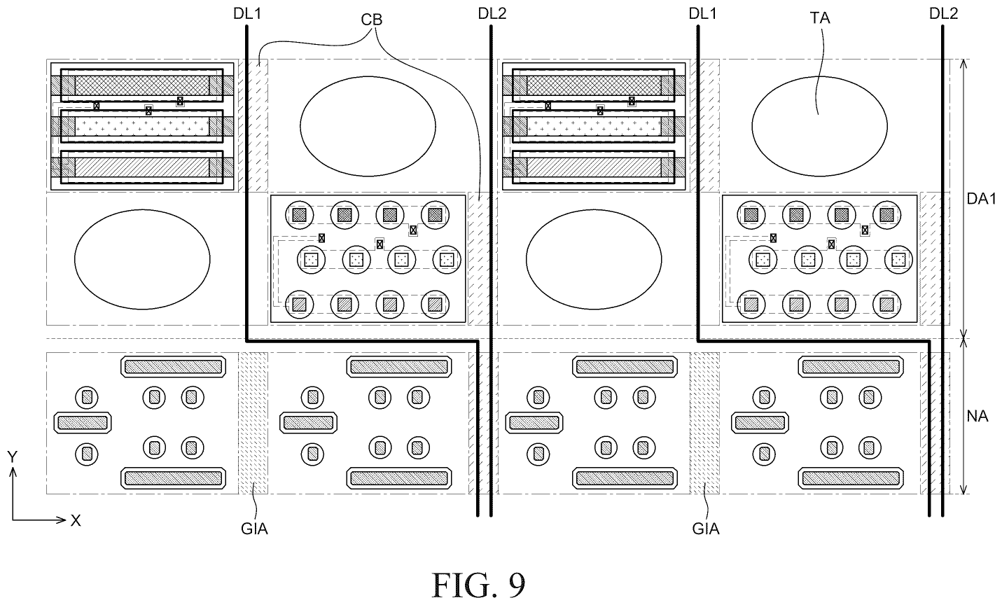

FIG. 9 is a view for describing an example of driving of the normal area and the first optical area of the display device of one embodiment. In FIG. 9, an emission area comprising sub pixels constituting a normal area and a first optical area, a transmittance area, a circuit area and a data line are only described for convenience of description.

Referring to FIG. 9, a first emission area and a transmittance area of a first optical area are disposed alternately in the row direction (the X-axis direction) and the column direction (the Y-axis direction), and a second emission area and a transmittance area of the first optical area are disposed alternately in the row direction (the X-axis direction) and the column direction (the Y-axis direction). A unit pixel of the normal area is disposed to surround the first optical area.

A first data line DLI connects to a first column (a n^{th} column), and a second data line DL2 connect to a second column (a n+1^{th} column). The sub pixels of the first emission area EA1 disposed in the first column connects to a first data line DL1, and the sub pixels of the second emission area EA2 disposed in the second column connect to a second data line DL2.

The first data line DLI reaches the normal area, moves in the row direction (the X-axis direction), and connects to the emission area of the second column (a n+1^{th} column) of the normal area. Additionally, although the second data line DL2 reaches the normal area, the second data line DL2 continues to extend in the column direction (the Y-axis direction), and connects to the emission area of the second column (a n+1^{th} column). The first data line DLI and the second data line DL2 having reached the normal area connect to the second column and a third column placed at both sides of thereof.

Based on the arrangement illustrated in FIG. 9, the first data line DLI delivers a second emission signal to sub pixels disposed in the first emission area of the first optical area, and the second data line DL2 delivers a third emission signal to sub pixels disposed in the second emission area of the first optical area. Additionally, the first data line DLI and the second data line DL2 having reached the normal area may respectively deliver both the second emission signal and the third emission signal to sub pixels placed at both sides of thereof.

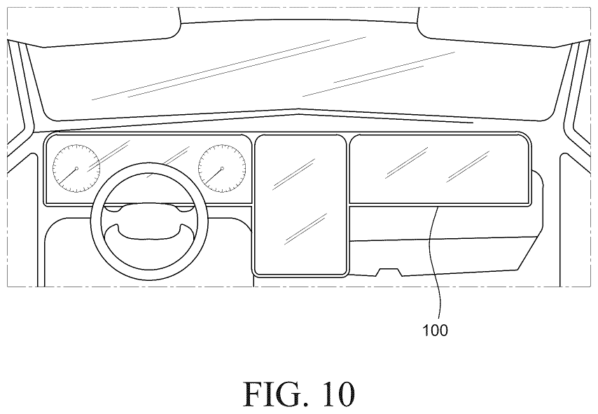

FIG. 10 is a view of an example of a display device of one embodiment.

A display device 100 of one embodiment may be disposed in at least part of the dashboard of a vehicle. The dashboard comprises components disposed on the front surface of the front seat (e.g., a driver's seat, a passenger seat) of the vehicle. For example, in the dashboard, input components for manipulating a variety of functional devices (e.g., an air conditioner, an audio system, a navigation system) in the vehicle may be disposed.

The display device 100 of one embodiment may be disposed in the dashboard of a vehicle and operate as an input part for manipulating at least part of a variety of functions of the vehicle. The display device 100 may provide various types of information on the vehicle, for example, operation information (e.g., a current speed, amounts of remaining fuels, and a driving distance) of the vehicle, information on parts of the vehicle (e.g., a wear degree of a tire).

The display device 100 may be disposed across the driver's seat and the passenger seat disposed at the front of the vehicle. The user of the display device 100 may comprise a driver of the vehicle and a passenger on the passenger seat of the vehicle. Both the driver and the passenger may use the display device 100.

In FIG. 10, part of the display device 100 may only be illustrated. In FIG. 10, a display panel may be illustrated among a variety of components included in the display device 100. Specifically, FIG. 8 shows at least part of the display area and the non-display area of the display panel, in the display device 100, for example. Among the components of the display device 100, components, except for the components illustrated in FIG. 10, may be mounted in a vehicle (or at least part of a vehicle).

The exemplary embodiments of the present disclosure can also be described as follows:

According to an aspect of the present disclosure, there is provided a display device. The display device includes a substrate on which a plurality of sub pixels is disposed, and that comprises a first display area comprising a first emission area, a second emission area and a transmittance area, and a second display area surrounding the first display area. Each of the sub pixels disposed on the second display area, comprise a first thin film transistor and a second thin film transistor; a first emitting diode comprising a first anode connecting to the first thin film transistor, a first emission layer and a cathode electrode; a second emitting diode comprising a second anode electrode connecting to the second thin film transistor, a second emission layer and the cathode electrode, and emitting light of the same color as light of the first emitting diode; and a first lens corresponding to the first emitting diode and refracting light from the first emitting diode, and a second lens corresponding to the second emitting diode and refracting light from the second emitting diode. Each of the sub pixels disposed in the first emission area comprise a third thin film transistor; a third emitting diode comprising a third anode electrode connecting to the third thin film transistor, a third emission layer and a cathode electrode; and a third lens corresponding to the third emitting diode and refracting light from the third emitting diode. Each of the sub pixels disposed in the second emission area comprise a fourth thin film transistor; a fourth emitting diode comprising a fourth anode electrode, connecting to the fourth thin film transistor, a fourth emission layer and a cathode electrode; and a fourth lens corresponding to the fourth emitting diode and refracting light from the fourth emitting diode.

The first emission layer and the second emission layer may connect to each other and may be formed integrally.

The first lens and the third lens may be half-spherical lenses, and the second lens and the fourth lens may be half-cylindrical lenses.

The display device may be selectively driven in a narrow field of view mode and a wide field of view mode. In the narrow field of view mode, the first emitting diode emits light so that the light from the first emitting diode may be output in such a way that a viewing angle of the light from the first emitting diode is limited by the first lens with respect to a first direction and a second direction, and the third emitting diode emits light so that the light from the third emitting diode is output in such a way that a viewing angle of the light from the third emitting diode is limited by the third lens with respect to a first direction and a second direction. In the wide field of view mode, the second emitting diode may emit light so that the light from the second emitting diode is output in such a way that a viewing angle of the light from the second emitting diode is limited by the second lens only with respect to a first direction, and the fourth emitting diode emits light so that light from the fourth emitting diode is output in such a way that a viewing angle of the light from the fourth emitting diode is limited by the fourth lens only with respect to a first direction.

The plurality of sub pixels may comprise red, green and blue sub pixels. Each of the sub pixels disposed in the first display area may have a greater size than each of the plurality of sub pixels disposed in the second display area emitting light of a corresponding color.

The display device may further comprise a bank layer that is disposed on the substrate and comprise a first opening exposing the first anode electrode, a second opening exposing the second anode electrode and a third opening exposing the third anode electrode, and a fourth opening exposing the fourth anode electrode. The number of the third openings of each of the sub pixels disposed in the first emission area may be greater than the number of the first openings of each of the sub pixels disposed in the second display area emitting light of a corresponding color.

The number of the third lenses disposed in each of the sub pixels of the first emission area may be greater than the number of the first lenses disposed in each of the sub pixels of the second display area emitting light of a corresponding color.

The first emission area and the transmittance area may be alternately arranged in a first direction and a second direction perpendicular to the first direction, and the second emission area and the transmittance area may be alternately arranged in the first direction and the second direction.

The display device may further comprise a gate line extending in a row direction; and a data line extending in a column direction and crossing the gate line. The data line may comprise a first data line disposed in a n^{th} column and connected to the third emitting diode of the sub pixels of the first emission area, and a second data line disposed in a n+1 column and connected to the fourth emitting diode of the sub pixels of the second emission area, wherein, n is a natural number greater than or equal to 1.

The second data line may continue to extend toward the column direction, when the second data line extends to the second display area. The first data line may move in the row direction and extend near the second data line in the n+1 column, when the first data line extends to the second display area.

The first data line may connect to the first emitting diode of sub pixels disposed at both sides thereof. The second data line may connect to the second emitting diode of sub pixels disposed at both sides thereof.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate on which a plurality of sub pixels is disposed, and that comprises a first display area comprising a first emission area, a second emission area and a transmittance area, and a second display area surrounding the first display area, wherein
each of the sub pixels disposed on the second display area, comprising:
a first thin film transistor and a second thin film transistor;
a first emitting diode comprising a first anode electrode connecting to the first thin film transistor, a first emission layer and a cathode electrode;
a second emitting diode comprising a second anode electrode connecting to the second thin film transistor, a second emission layer and the cathode electrode, and emitting light of the same color as light of the first emitting diode; and
a first lens corresponding to the first emitting diode and refracting light from the first emitting diode, and a second lens corresponding to the second emitting diode and refracting light from the second emitting diode,
each of the sub pixels disposed in the first emission area, comprising:
a third thin film transistor;
a third emitting diode comprising a third anode electrode connecting to the third thin film transistor, a third emission layer and a cathode electrode; and
a third lens corresponding to the third emitting diode and refracting light from the third emitting diode,
each of the sub pixels disposed in the second emission area, comprising:
a fourth thin film transistor;
a fourth emitting diode comprising a fourth anode electrode connecting to the fourth thin film transistor, a fourth emission layer and a cathode electrode; and
a fourth lens corresponding to the fourth emitting diode and refracting light from the fourth emitting diode.

2. The display device of claim 1, wherein the first emission layer and the second emission layer connect to each other and are formed integrally.

3. The display device of claim 1, wherein the first lens and the third lens are half-spherical lenses, and
the second lens and the fourth lens are half-cylindrical lenses.

4. The display device of claim 1, wherein the display device is selectively driven in a narrow field of view mode and a wide field of view mode,
in the narrow field of view mode, the first emitting diode emits light so that the light from the first emitting diode is output in such a way that a viewing angle of the light from the first emitting diode is limited by the first lens with respect to a first direction and a second direction, and the third emitting diode emits light so that the light from the third emitting diode is output in such a way that a viewing angle of the light from the third emitting diode is limited by the third lens with respect to a first direction and a second direction, and
in the wide field of view mode, the second emitting diode emits light so that the light from the second emitting diode is output in such a way that a viewing angle of the light from the second emitting diode is limited by the second lens only with respect to a first direction, and the fourth emitting diode emits light so that light from the fourth emitting diode is output in such a way that a viewing angle of the light from the fourth emitting diode is limited by the fourth lens only with respect to a first direction.

5. The display device of claim 1, wherein the plurality of sub pixels comprises red, green and blue sub pixels, and
each of the sub pixels disposed in the first display area has a greater size than each of the plurality of sub pixels disposed in the second display area emitting light of a corresponding color.

6. The display device of claim 5, wherein the display device further comprises a bank layer that is disposed on the substrate and comprises a first opening exposing the first anode electrode, a second opening exposing the second anode electrode and a third opening exposing the third anode electrode, and a fourth opening exposing the fourth anode electrode, and
the number of the third openings of each of the sub pixels disposed in the first emission area is greater than the number of the first openings of each of the sub pixels disposed in the second display area emitting light of a corresponding color.

7. The display device of claim 6, wherein the number of the third lenses disposed in each of the sub pixels of the first emission area is greater than the number of the first lenses disposed in each of the sub pixels of the second display area emitting light of a corresponding color.

8. The display device of claim 1, wherein the first emission area and the transmittance area are alternately arranged in a first direction and a second direction perpendicular to the first direction, and
the second emission area and the transmittance area are alternately arranged in the first direction and the second direction.

9. The display device of claim 8, further comprising:
a gate line extending in a row direction; and
a data line extending in a column direction and crossing the gate line,
wherein the data line comprises a first data line disposed in a n^{th} column and connected to the third emitting diode of the sub pixels of the first emission area, and a second data line disposed in a n⁺¹ column and connected to the fourth emitting diode of the sub pixels of the second emission area, wherein, n is a natural number greater than or equal to 1.

10. The display device of claim 9, wherein the second data line continues to extend toward the column direction, when the second data line extends to the second display area, and
the first data line moves in the row direction and extends near the second data line in the n⁺¹ column, when the first data line extends to the second display area.

11. The display device of claim 10, wherein the first data line connects to the second emitting diode of sub pixels disposed at both sides thereof, and
the first data line connects to the second emitting diode of sub pixels disposed at both sides thereof.

12. The display device of claim 4, wherein in the narrow field of view mode, the viewing angle of the light that is limited by the first lens or the third lens is 30 degrees or less, and in the wide field of view mode, the viewing angle of the light that is limited by the second lens or the fourth lens is 60 degrees or greater.
